(19) United States
(12) Patent Application Publication
(10) Pub. No.: US 2017/0204241 A1
(43) Pub. Date: Jul. 20, 2017

(54) ELECTRICALLY CONDUCTIVE POLYMER COMPLEXES AND ELECTRONIC DEVICES CONTAINING SUCH COMPLEXES

(71) Applicant: RHODIA OPERATIONS, Paris (FR)

(72) Inventors: Amelie NICOLAY, Brussels (BE); Bertrand PAVAGEAU, Villenave d'Ornon (FR); Chantal BADRE, Millstone, NJ (US); Lawrence Alan HOUGH, Yongsan-gu, Seoul (KR)

(21) Appl. No.: 15/324,943

(22) PCT Filed: Jul. 9, 2015
(86) PCT No.: PCT/US2015/039748

§ 371 Date: Jan. 9, 2017

Related U.S. Application Data
(60) Provisional application No. 62/023,222, filed on Jul. 11, 2014.

(51) Int. Cl. C08J 9/28; C08J 9/00; H01L 29/84; H01L 35/24; H01L 31/0224; H01L 33/40; H01M 4/62; H01M 10/0525; H01M 10/0567; H01M 4/131; H01M 4/134; H01M 4/133; H01M 4/38; H01M 4/525; H01M 4/587; H01M 4/485; C08L 65/00

(52) U.S. Cl. CPC C08J 9/28; C08L 65/00; C08J 9/0061; H01L 29/84; H01L 35/24; H01L 31/0224; H01L 33/40; H01M 4/624; H01M 10/0525; H01M 10/0567; H01M 4/131; H01M 4/134; H01M 4/133; H01M 4/38; H01M 4/525; H01M 4/587; H01M 4/485; C08J 2201/0484; C08J 2201/0504; C08J 2205/026; C08J 2207/00; C08J 2465/00; H01M 2004/027

(57) ABSTRACT

Described herein are polymer complexes, including polymer gels and polymer foams, containing electrically conductive polymers and ionic liquids. The polymer complexes described herein are useful as components of electronic devices.

### CROSS REFERENCE TO RELATED APPLICATIONS

This application claims the priority of U.S. Provisional Application No. 62/023,222, filed Jul. 11, 2014. The entire content of this application is explicitly incorporated herein by this reference.

### FIELD OF THE INVENTION

The present invention relates to polymer complexes comprising electrically conductive polymers and ionic liquids, and electronic devices containing such complexes.

### BACKGROUND

Electrically conductive polymers, such as polythiophene polymers, particularly a polymer blend of poly(3,4-ethylenedioxythiophene) and poly(styrene sulfonate) (“PEDOT-PSS”), have been investigated as possible alternatives to metallic coatings, particularly ITO coatings, for use in various applications requiring high electrical conductivity. The electrical conductivity of electrically conductive polymers is typically lower than that of ITO, but can be enhanced through the use of conductive fillers, such as carbon nanotubes, and dopants. However, the performance of such materials still falls short of that of ITO and trade-offs exist between optimizing the electrical conductivity and optimizing the price, optical transparency, and physical resiliency of components comprising electrically conductive polymers.

The properties of PEDOT:PSS thin films have been studied, but studies of the properties of bulk gels and PEDOT:PSS materials having thicknesses in the range of tens to hundreds of micrometers have heretofore been lacking. Such materials are very promising, however, because high electrical conductivity in conjunction with malleability presents the possibility of manufacturing deformable electrodes and/or organic conductors for use in a wide variety of applications. In addition, the presence of piezoresistive properties in bulk materials is advantageous in pressure-sensing applications.

There is an ongoing unresolved interest in increasing the electrical conductivity of electrically conductive polymers, more specifically of PEDOT-PSS, as well as adapting them for use in industrial applications.

### SUMMARY OF THE INVENTION

In a first aspect, the present disclosure relates to a polymer composition comprising:

(a) at least one electrically conductive polymer,

(b) optionally one or more polymeric acid dopants,

(c) at least one ionic liquid,

(d) a liquid medium, and

(e) optionally one or more additives.

In a second aspect, the present disclosure relates to a polymer gel and a process for forming a polymer gel, the process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer, and
(II) allowing the gel to form.

In a third aspect, the present disclosure relates to a polymer foam and a process for forming a polymer foam, the process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer,
(II) allowing the gel to form, and
(III) removing from the gel any liquid remaining on or in the gel.

In a fourth aspect, the present disclosure relates to a piezoresistive device comprising:

(I) a polymer foam or a polymer gel described herein, and

(II) a first and second electrode.

In a fifth aspect, the present disclosure relates to an electronic device comprising:
(a) an anode layer,
(b) a cathode layer,
(c) an electroactive layer disposed between the anode layer and the cathode layer,
(d) optionally, a buffer layer,
(e) optionally, a hole transport layer, and
(f) optionally, an electron injection layer,
   wherein at least one of the anode layer, the cathode layer, and, if present, the buffer layer comprises a polymer foam or a polymer gel described herein.

In a sixth aspect, the present disclosure relates to a battery comprising:
a first electrode,
at least one electrolyte, and
a second electrode,
wherein at least one of the first electrode, the electrolyte, and the second electrode comprises a polymer foam or a polymer gel described herein.

In a seventh aspect, the present disclosure relates to a thermoelectric device comprising:
a first electrode,
at least one electrolyte, and
a second electrode;
   wherein at least one of the first electrode, the at least one electrolyte, and the second electrode comprises a polymer foam or a polymer gel described herein.

### BRIEF DESCRIPTION OF THE DRAWINGS

FIGS. 1A and 1B show optical microscope images of the surface of a thin layer of the foam materials of the present invention at 40× magnification.

FIG. 2 shows the Raman spectrum of PEDOT:PSS films obtained by others (Schaarschmidt, et al. Influence of Nonadiabatic Annealing on the Morphology and Molecular Structure of PEDOT-PSS Films. Journal of Physical Chemistry B, 113: 9352-9355, 2009). The dotted lines encircle peaks due to the silicon substrate used in obtaining the spectrum.

FIG. 3 shows the Raman spectra of a thin layer of the inventive foam materials: rinsed (light color) and unrinsed (dark color). Spectral resolution is 1.5 cm⁻¹.

FIG. 4 shows a magnified portion of the spectrum shown in FIG. 3. Spectral resolution is 0.5 cm⁻¹.

FIG. 5 shows scanning electron microscope (SEM) images of thin layers of various foam materials of the present invention: (A) gelation time of 60 minutes, foam formed without rinsing; (B) gelation time of 90 minutes, foam formed without rinsing; (C) gelation time of 90 minutes, foam is rinsed with agitation; (D) gelation time of 120 minutes, foam formed without rinsing; (E) gelation time of 120 minutes, foam is rinsed without agitation; and (F) gelation time of 120 minutes, foam is rinsed with agitation.

FIG. 6 shows the apparatus used for lengthwise measurement of conductivity. (A) is a schematic diagram and (B) is a photograph of the glass slide, wires, and foam material sample.

FIG. 7 shows the apparatus used for a through-thickness measurement of conductivity and impedance. (a) shows the use of copper tape as electrodes with conductive paste, (b) shows the use of a commercially-available electrode setup, and (c) shows a schematic diagram of the apparatus.

FIG. 8 shows impedance characteristics of the foam materials of the present invention: (A) is a Bode plot of impedance as a function of frequency and (B) is a phase diagram showing reactance as a function of resistance. Reactance is higher at high frequencies due to the measuring instrument.

FIG. 9 shows the apparatus used to measure the piezoresistive properties of the foam material of the present invention. (A) and (B) are various views of the schematic diagram of the apparatus and (C) is a photograph of the apparatus.

FIG. 10 shows a plot of stress as a function of strain. The Young's modulus of the sample was obtained by linear regression.

FIG. 11 shows the electrical resistance variation of the foam material as a function of the stress and Young's modulus of the particular inventive foam material. A gauge factor of 12.1 was obtained for sample A (gelation time of 60 minutes) and 17.1 for sample B (gelation time of 90 minutes).

FIG. 12 shows the schematic diagram of a piezoresistive device 120.

FIG. 13 shows the schematic diagram of a piezoresistive device 130.

FIG. 14 shows the schematic diagram of an electronic device 140.

FIG. 15 shows a) PEDOT:PSS and ionic liquid composition; b) PEDOT:PSS and ionic liquid composition after 1 hour (polymer gel formed); and c) inventive foam prepared by removing remaining liquid by freeze-drying.

### DETAILED DESCRIPTION OF THE INVENTION

As used herein, the terms “a”, “an”, or “the” means “one or more” or “at least one” unless otherwise stated.

As used herein, the term “comprises” includes “consists essentially of” and “consists of”. The term “comprising” includes “consisting essentially of” and “consisting of”.

As used herein, the following terms have the meanings ascribed below:

“acidic group” means a group capable of ionizing to donate a hydrogen ion,

“anode” means an electrode that is more efficient for injecting holes compared to than a given cathode,

“buffer layer” generically refers to electrically conductive or semiconductive materials or structures that have one or more functions in an electronic device, including but not limited to, planarization of an adjacent structure in the device, such as an underlying layer, charge transport and/or charge injection properties, scavenging of impurities such as oxygen or metal ions, and other aspects to facilitate or to improve the performance of the electronic device,

“cathode” means an electrode that is particularly efficient for injecting electrons or negative charge carriers,

“confinement layer” means a layer that discourages or prevents quenching reactions at layer interfaces,

“doped” as used herein in reference to an electrically conductive polymer means that the electrically conductive polymer has been combined with a polymer counterion for the electrically conductive polymer, which polymer counterion is referred to herein as “dopant”, and is typically a polymer acid, which is referred to herein as a “polymer acid dopant”,

“doped electrically conductive polymer” means a polymer blend comprising an electrically conductive polymer and a polymer counterion for the electrically conductive polymer,

“electrically conductive polymer” means any polymer or polymer blend that is inherently or intrinsically, without the addition of electrically conductive fillers such as carbon black or conductive metal particles, capable of electrical conductivity, more typically to any polymer or oligomer that exhibits a bulk specific conductance of greater than or equal to 10⁻⁷ Siemens per centimeter (“S/cm”), unless otherwise indicated, a reference herein to an “electrically conductive polymer” include any optional polymer acid dopant,

“electrically conductive” includes conductive and semi-conductive,

“electroactive” when used herein in reference to a material or structure, means that the material or structure exhibits electronic or electro-radiative properties, such as emitting radiation or exhibiting a change in concentration of electron-hole pairs when receiving radiation,

“electronic device” means a device that comprises one or more layers comprising one or more semiconductor materials and makes use of the controlled motion of electrons through the one or more layers,

“electron injection/transport”, as used herein in reference to a material or structure, means that such material or structure that promotes or facilitates migration of negative charges through such material or structure into another material or structure,

“high-boiling solvent” refers to an organic compound which is a liquid at room temperature and has a boiling point of greater than 100° C.,

“hole transport” when used herein when referring to a material or structure, means such material or structure facilitates migration of positive charges through the thickness of such material or structure with relative efficiency and small loss of charge,

“layer” as used herein in reference to an electronic device, means a coating covering a desired area of the device, wherein the area is not limited by size, that is, the area covered by the layer can, for example, be as large as an entire device, be as large as a specific functional area of the device, such as the actual visual display, or be as small as a single sub-pixel,

“polymer” includes homopolymers and copolymers, and

“polymer blend” means a blend of two or more polymers.

As used herein, the term “polymer complex” refers to one or more polymers optionally in combination with one or more non-polymeric materials wherein the one or more polymers and the optional one or more non-polymeric materials are interconnected by means other than covalent bonds (such as, for example, physical entanglements, hydrogen bonds, or ionic bonds) or by both covalent bonds and by means other than covalent bonds. Polymer complexes include, but are not limited to, polymer gels, polymer foams, and the like.

As used herein, the term “polymer gel”, “gel” or “gel material” refers to a polymer complex that is characterized as a solid and a continuous liquid phase.

As used herein, the term “polymer foam”, “foam”, or “foam material” refers to a polymer complex that is characterized as a solid and a continuous gas phase.

As used herein, the terminology “(Cₓ-C_{y})” in reference to an organic group, wherein x and y are each integers, means that the group may contain from x carbon atoms to y carbon atoms per group.

As used herein, the term “halo” means a halogen or halide radical and includes, for example, fluoride (F), chloride (Cl), bromide (Br), iodide (I), and astatide (At).

As used herein, the term “alkyl” means a monovalent straight, branched or cyclic saturated hydrocarbon radical, more typically, a monovalent straight or branched saturated (C₁-C₄₀)hydrocarbon radical, such as, for example, methyl, ethyl, n-propyl, isopropyl, n-butyl, isobutyl, tert-butyl, hexyl, octyl, hexadecyl, octadecyl, eicosyl, behenyl, tricontyl, and tetracontyl. As used herein, the term “cycloalkyl” means a saturated hydrocarbon radical, more typically a saturated (C₅-C₂₂) hydrocarbon radical, that includes one or more cyclic alkyl rings, which may optionally be substituted on one or more carbon atoms of the ring with one or two (C₁-C₆)alkyl groups per carbon atom, such as, for example, cyclopentyl, cycloheptyl, cyclooctyl.

The term “heteroalkyl” means an alkyl group wherein one or more of the carbon atoms within the alkyl group has been replaced by a hetero atom, such as, for example, nitrogen, oxygen, or sulfur.

The term “haloalkyl” means an alkyl radical, more typically a (C₁-C₂₂)alkyl radical, that is substituted with one or more halogen atoms, such as fluorine, chlorine, bromine, and iodine. Examples of haloalkyl groups include, for example, trifluoromethyl, 1H,1H,2H,2H-perfluorooctyl, perfluoroethyl.

As used herein, the term “hydroxyalkyl” means an alkyl radical, more typically a (C₁-C₂₂)alkyl radical, that is substituted with one or more hydroxyl groups, including, for example, hydroxymethyl, hydroxyethyl, hydroxypropyl, and hydroxydecyl.

As used herein, the term “alkoxyalkyl” means an alkyl radical that is substituted with one or more alkoxy substituents, more typically a (C₁-C₂₂)alkyloxy-(C₁-C₆)alkyl radical, including, for example, methoxymethyl, ethoxyethyl, and ethoxybutyl.

As used herein, the term “alkenyl” means an unsaturated straight or branched hydrocarbon radical, more typically an unsaturated straight, branched, (C₂-C₂₂) hydrocarbon radical, that contains one or more carbon-carbon double bonds, including, for example, ethenyl (vinyl), n-propenyl, and iso-propenyl, and allyl.

As used herein, the term “cycloalkenyl” means an unsaturated hydrocarbon radical, typically an unsaturated (C₅-C₂₂) hydrocarbon radical, that contains one or more cyclic alkenyl rings and which may optionally be substituted on one or more carbon atoms of the ring with one or two (C₁-C₆)alkyl groups per carbon atom, including, for example, cyclohexenyl and cycloheptenyl.

As used herein, the term “alkynyl” means an unsaturated straight or branched hydrocarbon radical, more typically an unsaturated straight, branched, (C₂-C₂₂) hydrocarbon radical, that contains one or more carbon-carbon triple bonds, including, for example, ethynyl, propynyl, and butynyl.

As used herein, the term “aryl” means a monovalent unsaturated hydrocarbon radical containing one or more six-membered carbon rings in which the unsaturation may be represented by three conjugated double bonds. Aryl radicals include monocyclic aryl and polycyclic aryl. “Polycyclic aryl” refers to a monovalent unsaturated hydrocarbon radical containing more than one six-membered carbon ring in which the unsaturation may be represented by three conjugated double bonds wherein adjacent rings may be linked to each other by one or more bonds or divalent bridging groups or may be fused together. Aryl radicals may be substituted at one or more carbons of the ring or rings with hydroxyl, cyano, alkyl, alkoxyl, alkenyl, halo, haloalkyl, monocyclic aryl, amino, —(C═O)-alkyl, —(C═O)O-alkyl, —(C═O)-haloalkyl, or —(C═O)— (monocyclic aryl). Examples of aryl radicals include, but are not limited to, phenyl, methylphenyl, isopropylphenyl, tert-butylphenyl, methoxyphenyl, dimethylphenyl, trimethylphenyl, chlorophenyl, trichloromethylphenyl, triisobutyl phenyl, anthracenyl, naphthyl, phenanthrenyl, fluorenyl, and pyrenyl.

As used herein, the term “aralkyl” means an alkyl group substituted with one or more aryl groups, more typically a (C₁-C₁₈)alkyl substituted with one or more (C₆-C₁₄)aryl substituents, including, for example, phenylmethyl (benzyl), phenylethyl, and triphenylmethyl.

As used herein, the term “heterocycle” or “heterocyclic” refers to compounds having a saturated or partially unsaturated cyclic ring structure that includes one or more hetero atoms in the ring. The term “heterocyclyl” refers to a monovalent group having a saturated or partially unsaturated cyclic ring structure that includes one or more hetero atoms in the ring. Examples of heterocyclyl groups include, but are not limited to, morpholinyl, piperadinyl, piperazinyl, pyrrolinyl, pyrazolyl, and pyrrolidinyl.

As used herein, the term “heteroaryl” means a monovalent group having at least one aromatic ring that includes at least one hetero atom in the ring, which may be substituted at one or more atoms of the ring with hydroxyl, alkyl, alkoxyl, alkenyl, halo, haloalkyl, monocyclic aryl, or amino. Examples of heteroaryl groups include, but are not limited to, thienyl, pyrrolyl, pyridinyl, pyrimidinyl, pyrazinyl, triazinyl, pyridazinyl, tetrazolyl, and imidazolyl groups. The term “polycyclic heteroaryl” refers to a monovalent group having more than one aromatic ring, at least one of which includes at least one hetero atom in the ring, wherein adjacent rings may be linked to each other by one or more bonds or divalent bridging groups or may be fused together. Examples of polycyclic heteroaryl groups include, but are not limited to, indolyl and quinolinyl groups.

Any alkyl, haloalkyl, hydroxyalkyl, alkoxyalkyl, alkoxyl, alkenyl, cycloalkenyl, alkynyl, aryl, aralkyl, heterocyclyl, or heteroaryl groups described herein may optionally be substituted at one or more carbon atoms with hydroxyl, cyano, alkyl, alkoxyl, alkenyl, halo, haloalkyl, monocyclic aryl, amino, —(C═O)-alkyl, —(C═O)O-alkyl, —(C═O)-haloalkyl, or —(C═O)-(monocyclic aryl).

As used herein, the following terms refer to the corresponding substituent groups:

“amido” is —R¹—C(O)N(R⁶)R⁶,

“amidosulfonate” is —R¹—C(O)N(R⁴)R²-SO₃Z,

“benzyl” is —CH₂—C₆H₅,

“carboxylate” is —R¹—C(O)O—Z or —R¹-O-—C(O)—Z,

“ether” is —R¹—(O—R³)ₚ—O—R³,

“ether carboxylate” is —R¹—O—R²—C(O)O—Z or —R¹—O—R²—O—C(O)—Z,

“ether sulfonate” is —R¹—O—R²—SO₃Z,

“ester sulfonate” is —R¹—O—C(O)R²—SO₃Z, and

“urethane” is —R¹—O—C(O)—N(R⁴)₂, wherein:

each R¹ is absent or alkylene,

each R² is alkylene,

each R³ is alkyl,

each R⁴ is H or an alkyl,

is 0 or an integer from 1 to 20, and

each Z is H, alkali metal, alkaline earth metal, N(R³)₄ or R³, wherein any of the above groups may be non-substituted or substituted, and any group may have fluorine substituted for one or more hydrogens, including perfluorinated groups.

The electrically conductive polymer component of the polymer complexes and/or polymer complex component of the electronic device of the present invention may each comprise one or more homopolymers, one or more co-polymers of two or more respective monomers, or a mixture of one or more homopolymers and one or more copolymers. The respective electrically conductive polymer complexes, and/or polymer complex component of the electronic device of the present invention may each comprise a single polymer or may comprise a blend two or more polymers which differ from each other in some respect, for example, in respect to composition, structure, or molecular weight.

In an embodiment, the electrically conductive polymer component of the polymer complexes and/or polymer complex component of the electronic device comprises one or more electrically conductive polymers selected from electrically conductive polythiophene polymers, electrically conductive poly(selenophene) polymers, electrically conductive poly(telurophene) polymers, electrically conductive polypyrrole polymers, electrically conductive polyaniline polymers, electrically conductive fused polycylic heteroaromatic polymers, and blends of any such polymers.

In one embodiment, the electrically conductive polymer comprises one or more polymers selected from electrically conductive polythiophene polymers, electrically conductive poly(selenophene) polymers, electrically conductive poly(telurophene) polymers, and mixtures thereof Suitable polythiophene polymers, poly(selenophene) polymers, poly(telurophene) polymers and methods for making such polymers are generally known. In one embodiment, the electrically conductive polymer comprises at least one electrically conductive polythiophene polymer, electrically conductive poly(selenophene) polymer, or electrically conductive poly(telurophene) polymer that comprises 2 or more, more typically 4 or more, monomeric units according to structure (I) per molecule of the polymer:

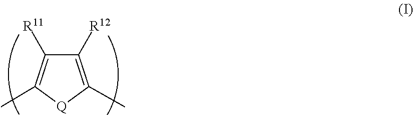

wherein:

Q is S, SE, or Te, and

each occurrence of R¹¹ and each occurrence of R¹² is independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, ether carboxylate, amidosulfonate, ether sulfonate, ester sulfonate, and urethane, or both the R¹¹ group and R¹² group of a given monomeric unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, selenium, tellurium, sulfur, or oxygen atoms.

In one embodiment, Q is S, the R¹¹ and R¹² of the monomeric unit according to structure (I) are fused and the electrically conductive polymer comprises a polydioxythiopene polymer that comprises 2 or more, more typically 4 or more, monomeric units according to structure (I.a) per molecule of the polymer:

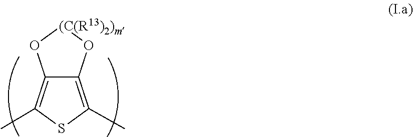

wherein:

each occurrence of R¹³ is independently H, alkyl, hydroxyl, heteroalkyl, alkenyl, heteroalkenyl, hydroxalkyl, amidosulfonate, benzyl, carboxylate, ether, ether carboxylate, ether sulfonate, ester sulfonate, or urethane, and

m′ is 2 or 3.

In one embodiment, all R¹³ groups of the monomeric unit according to structure (I.a) are each H, alkyl, or alkenyl. In one embodiment, R¹³ groups of the monomeric unit according to structure (I.a) are not each H. In one embodiment, each R¹³ groups of the monomeric unit according to structure (I.a) is H.

In one embodiment, the electrically conductive polymer comprises an electrically conductive polythiophene homopolymer of monomeric units according to structure (I.a) wherein each R¹³ is H and m′ is 2, known as poly(3,4-ethylenedioxythiophene), more typically referred to as “PEDOT”.

In one embodiment, the electrically conductive polymer comprises one or more electrically conductive polypyrrole polymers. Suitable electrically conductive polypyrrole polymers and methods for making such polymers are generally known. In one embodiment, the electrically conductive polymer comprises a polypyrrole polymer that comprises 2 or more, more typically 4 or more, monomeric units according to structure (II) per molecule of the polymer:

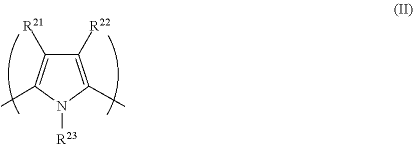

wherein:

each occurrence of R²¹ and each occurrence of R²² is independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, amidosulfonate, ether carboxylate, ether sulfonate, ester sulfonate, and urethane, or the R²¹ and R²² of a given pyrrole unit are fused to form, together with the carbon atoms to which they are attached, an alkylene or alkenylene chain completing a 3, 4, 5, 6, or 7-membered aromatic or alicyclic ring, which ring may optionally include one or more divalent nitrogen, sulfur or oxygen atoms, and

each occurrence of R²³ is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, hydroxyl, hydroxyalkyl, benzyl, carboxylate, ether, ether carboxylate, ether sulfonate, ester sulfonate, and urethane

In one embodiment, each occurrence of R²¹ and each occurrence of R²² is independently H, alkyl, alkenyl, alkoxy, cycloalkyl, cycloalkenyl, hydroxyl, hydroxyalkyl, benzyl, carboxylate, ether, amidosulfonate, ether carboxylate, ether sulfonate, ester sulfonate, urethane, epoxy, silane, siloxane, or alkyl, wherein the alky group may optionally be substituted with one or more of sulfonic acid, carboxylic acid, acrylic acid, phosphoric acid, phosphonic acid, halogen, nitro, cyano, hydroxyl, epoxy, silane, or siloxane moieties.

In one embodiment, each occurrence of R²³ is independently H, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one embodiment, each occurrence of R²¹, R², and R²³ is H.

In one embodiment, R²¹ and R²² are fused to form, together with the carbon atoms to which they are attached, a 6- or 7-membered alicyclic ring, which is further substituted with a group selected from alkyl, heteroalkyl, hydroxyl, hydroxyalkyl, benzyl, carboxylate, ether, ether carboxylate, ether sulfonate, ester sulfonate, and urethane. In one embodiment, and R²² are fused to form, together with the carbon atoms to which they are attached, a 6- or 7-membered alicyclic ring, which is further substituted with an alkyl group. In one embodiment, R²¹ and R²² are fused to form, together with the carbon atoms to which they are attached, a 6- or 7-membered alicyclic ring, which is further substituted with an alkyl group having at least 1 carbon atom.

In one embodiment, R²¹ and R²² are fused to form, together with the carbon atoms to which they are attached, a —O—(CHR²⁴)n′-O— group, wherein:

each occurrence of R²⁴ is independently H, alkyl, hydroxyl, hydroxyalkyl, benzyl, carboxylate, amidosulfonate, ether, ether carboxylate, ether sulfonate, ester sulfonate, and urethane, and

n′ is 2 or 3.

In one embodiment, at least one R²⁴ group is not hydrogen. In one embodiment, at least one R²⁴ group is a substituent having F substituted for at least one hydrogen. In one embodiment, at least one Y group is perfluorinated.

In one embodiment, the electrically conductive polymer comprises one or more electrically conductive polyaniline polymers. Suitable electrically conductive polyaniline polymers and methods of making such polymers are generally known. In one embodiment, the electrically conductive polymer comprises a polyaniline polymer that comprises 2 or more, more typically 4 or more, monomeric units selected from monomeric units according to structure (III) and monomeric units according to structure (III.a) per molecule of the polymer:

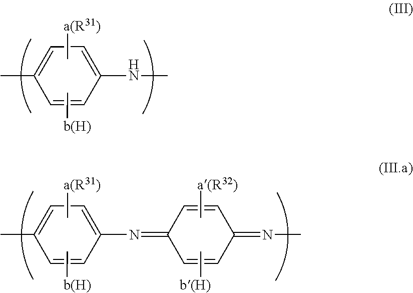

wherein:

each occurrence of R³¹ and R³² s independently alkyl, alkenyl, alkoxy, cycloalkyl, cycloalkenyl, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more of sulfonic acid, carboxylic acid, halo, nitro, cyano or epoxy moieties, or two R³¹ or R³² groups on the same ring may be fused to form, together with the carbon atoms to which they are attached, a 3, 4, 5, 6, or 7-membered aromatic or alicyclic ring, which ring may optionally include one or more divalent nitrogen, sulfur or oxygen atoms; and

each a and a′ is independently an integer from 0 to 4,

each b and b′ is integer of from 1 to 4, wherein, for each ring, the sum of the a and b coefficients of the ring or the a′ and b′ coefficients of the ring is 4.

In one embodiment, a or a′ =0 and the polyaniline polymer is an non-substituted polyaniline polymers referred to herein as a “PANI” polymer.

In one embodiment, the electrically conductive polymer comprises one or more electrically conductive polycylic heteroaromatic polymers. Suitable electrically conductive polycylic heteroaromatic polymers and methods for making such polymers are generally known. In one embodiment, the electrically conductive polymer comprises one or more polycylic heteroaromatic polymers that comprise 2 or more, more typically 4 or more, monomeric units per molecule that are derived from one or more heteroaromatic monomers, each of which is independently according to Formula (IV):

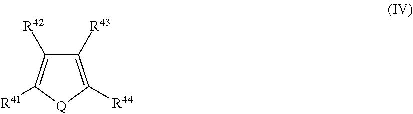

wherein:

Q is S or NH,

R⁴¹, R⁴², R⁴³, and R⁴⁴ are each independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, hydroxyl, hydroxyalkyl, benzyl, carboxylate, ether, ether carboxylate, amidosulfonate, ether sulfonate, ester sulfonate, or urethane, provided that at least one pair of adjacent substituents R⁴¹ and R⁴², R⁴² and R⁴³, or R⁴³ and R⁴⁴ are fused to form, together with the carbon atoms to which they are attached, a 5 or 6-membered aromatic ring, which ring may optionally include one or more hetero atoms, more typically selected from divalent nitrogen, sulfur and oxygen atoms, as ring members.

In one embodiment, the polycylic heteroaromatic polymers comprise 2 or more, more typically 4 or more, monomeric units per molecule that are derived from one or more heteroaromatic monomers, each of which is independently according to structure (V):

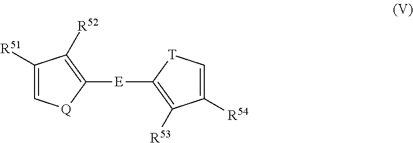

wherein:

Q is S, Se, Te, or NR⁵⁵,

T is S, Se, Te, NR⁵⁵, O, Si(R⁵⁵)₂, or PR⁵⁵,

E is alkenylene, arylene, and heteroarylene,

R⁵⁵ is hydrogen or alkyl,

R⁵¹, R⁵², R⁵³, and R⁵⁴ are each independently H, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, hydroxyl, hydroxyalkyl, benzyl, carboxylate, ether, ether carboxylate, amidosulfonate, ether sulfonate, and urethane, or where each pair of adjacent substituents R⁵¹ and R⁵² and adjacent substituents R⁵³ and R⁵⁴ may independently form, together with the carbon atoms to which they are attached, a 3, 4, 5, 6, or 7-membered aromatic or alicyclic ring, which ring may optionally include one or more hetero atoms, more typically selected from divalent nitrogen, sulfur and oxygen atoms, as ring members.

In one embodiment, the electrically conductive polymer comprises an electrically conductive copolymer that comprises at least one first monomeric unit per molecule that is according to formula (I), (I.a), (II), (III), or (III.a) or that is derived from a heteroaromatic monomer according to structure (IV) or (V) and further comprises one or more second monomeric units per molecule that differ in structure and/or composition from the first monomeric units. Any type of second monomeric units can be used, so long as it does not detrimentally affect the desired properties of the copolymer. In one embodiment, the copolymer comprises, based on the total number of monomer units of the copolymer, less than or equal to 50%, more typically less than or equal to 25%, even more typically less than or equal to 10% of second monomeric units.

Exemplary types of second monomeric units include, but are not limited to those derived from alkenyl, alkynyl, arylene, and heteroarylene monomers, such as, for example, fluorene, oxadiazole, thiadiazole, benzothiadiazole, phenylene vinylene, phenylene ethynylene, pyridine, diazines, and triazines, all of which may be further substituted, that are copolymerizable with the monomers from which the first monomeric units are derived.

In one embodiment, the electrically conductive copolymers are made by first forming an intermediate oligomer having the structure A-B-C, where A and C represent first monomeric units, which can be the same or different, and B represents a second monomeric unit. The A-B-C intermediate oligomer can be prepared using standard synthetic organic techniques, such as Yamamoto, Stille, Grignard metathesis, Suzuki and Negishi couplings. The electrically conductive copolymer is then formed by oxidative polymerization of the intermediate oligomer alone, or by copolymerization of the intermediate oligomer with one or more additional monomers.

In one embodiment, the electrically conductive polymer comprises an electrically conductive copolymer of two or more monomers. In one embodiment, the monomers comprise at least one monomer selected from a thiophene monomer, a pyrrole monomer, an aniline monomer, and a polycyclic aromatic monomer.

In one embodiment, the weight average molecular weight of the electrically conductive polymer is from about 1000 to about 2,000,000 grams per mole, more typically from about 5,000 to about 1,000,000 grams per mole, and even more typically from about 10,000 to about 500,000 grams per mole.

In one embodiment, the electrically conductive polymer of the polymer complex, and/or polymer complex of the electronic device of the present invention further comprises a dopant. Suitable dopants include, but are not limited to, sulfonate anions, for example, para-toluene sulfonate anion; polymeric acid dopants, and the like.

In one embodiment, the electrically conductive polymer of the polymer complex, and/or polymer complex of the electronic device of the present invention further comprises a polymeric acid dopant, typically (particularly where the liquid medium of the polymer composition is an aqueous medium), a water soluble polymeric acid dopant. In one embodiment, the electrically conductive polymers used in the new compositions and methods are prepared by oxidatively polymerizing the corresponding monomers in aqueous solution containing a water soluble acid, typically a water-soluble polymeric acid. In one embodiment, the acid is a polymeric sulfonic acid. Some non-limiting examples of the acids are poly(styrenesulfonic acid) (“PSSA”), poly(2-acrylamido-2-methyl-1-propanesulfonic acid) (“PAAMPSA”), and mixtures thereof. The acid anion provides the dopant for the conductive polymer. The oxidative polymerization is carried out using an oxidizing agent such as ammonium persulfate, sodium persulfate, and mixtures thereof. Thus, for example, when aniline is oxidatively polymerized in the presence of PMMPSA, the doped electrically conductive polymer blend PANI/PAAMPSA is formed. When ethylenedioxythiophene (EDOT) is oxidatively polymerized in the presence of PSSA, the doped electrically conductive polymer blend PEDOT/PSS is formed. The conjugated backbone of PEDOT is partially oxidized and positively charged. Oxidatively polymerized pyrroles and thienothiophenes also have a positive charge which is balanced by the acid anion.

In one embodiment, the water soluble polymeric acid selected from the polysulfonic acids, more typically, poly(styrene sulfonic acid), or poly(acrylamido-2-methyl-1-propane-sulfonic acid), or a polycarboxylic acid, such as polyacrylic acid polymethacrylic acid, or polymaleic acid.

The polymer complexes and/or polymer complex component of the electronic device of the present invention comprises an ionic liquid component.

Ionic liquids are salts that have a melting point of less than or equal to 100° C. In one embodiment, the ionic liquid has a melting point of less than or equal to 75° C., more typically less than or equal to 50° C. and even more typically less than or equal to 25° C.

In one embodiment, the ionic liquid comprises one or more organic or inorganic salts and have a melting point of less than or equal to 100° C.

In one embodiment, the ionic liquid consists entirely of cationic and anionic species.

Typical cations for suitable ionic liquid compounds include, for example:

ammonium or tetraalkyl ammonium cations, such as, for example, tetramethyl ammonium, tetrabutyl ammonium, tetrahexyl ammonium, butyltrimethyl ammonium, and methyltrioctyl ammonium cations,

guanidinium cations such as, for example, N,N,N′,N′-tetrahexyl-N″,N″-dimethylguanidinium cations,

imidazolium cations, more typically, imidazolium cations that are substituted with from 1 to 3, more typically 2 to 3, alkyl, hydroxyalkyl, and/or aryl substituents per boron atom, such as, for example, 1,3-dimethyl-imidazolium, 1-benzyl-3-methyl-imidazolium, 1-butyl-3-methyl-imidazolium, 1-ethyl-3-methyl-imidazolium, 1-hexyl-3-methyl-imidazolium, 1-methyl-3-propyl-imidazolium, 1-methyl-3-octyl-imidazolium, 1-methyl-3-tetradecyl-imidazolium, 1-methyl-3-phenyl-imidazolium, 1,2,3-trimethyl-imidazolium, 1,2-methyl-3-octyl-imidazolium, 1-butyl-2,3-dimethyl-imidazolium, 1-hexyl-2,3-methyl-imidazolium, and 1-(2-hydroxyethyl)-2,3-dimethyl-imidazolium cations,

morpholinium cations, such as, for example, N-methyl-morpholinium and N-ethyl-morpholinium cations,

phosphonium cations, such as for example, tetrabutyl phosphonium and tributylmethyl phosphonium cations,

piperidinium cations, such as, for example, 1-butyl-1-methyl-piperidinium and 1-methyl-1-propyl-piperidinium cations,

pyradazinium cations,

pyrazinium cations, such as, for example, 1-ethyl-4-methyl-pyrazinium, 1-octyl-4-propyl-pyrazinium cations,

pyrazolium cations, such as, for example, 1-ethyl-2,3,5-pyrazolinium cations,

pyridinium cations, such as for example, N-butyl-pyridinium, and N-hexyl-pyridinium cations,

pyrimidinium cations, such as, for example, 1-hexyl-3-propyl-pyrimidinium, 1-ethyl-3-methyl-pyrimidinium cations,

pyrrolidinium cations, such as for example, 1-butyl-1-methyl-pyrrolidinium and 1-methyl-1-propyl-pyrrolidinium cations,

pyrrolium cations, such as for example, 1,1-dimethyl-pyrrolium, 1-methyl-1-pentyl-pyrrolium cations,

pyrrolinium cations,

sulfonium cations, such as, for example, trimethyl sulfonium cations,

thiazolium cations,

oxazolium cations,

triazolium cations; and

inorganic cations, such as, for example, sodium (Na⁺), lithium (Li⁺), potassium (K⁺), rubidium (Rb⁺), cesium (Cs⁺), magnesium (Mg²⁺), calcium (Ca²⁺), strontium (Sr²⁺), barium (Ba²⁺), iron(III) (Fe³⁺), cooper(II) (Cu²⁺), silver(I) (Ag⁺), zinc(II) (Zn²⁺), yttrium(III) (Y³⁺), cobalt(II) (Co²⁺), tungsten(III) (W³⁺), zirconium(IV) (Zr⁴⁺), titanium(IV) (Ti⁴⁺), lanthanum(III) (La³⁺), cerium(III) (Ce³⁺), europium(III) (Eu³⁺), aluminum(III) (Al³⁺), gallium(III) (Ga³⁺), tin(II) (Sn²⁺), tin(IV) (Sn⁴⁺), bismuth(III) (Bi³⁺) and antimony(III) (Sb³⁺).

Typical anions for suitable ionic liquid compounds include, for example:

borate anions, such as, for example, tetrafluoroborate, tetracyanoborate, tetrakis-(p-(dimethyl(1H, 1H, 2H, 2H-perfluorooctyl)silyl)phenyl)borate, alkyltrifluoroborate, perfluoroalkyltrifluoroborate, and alkenyltrifluoroborate anions

carbonate anions such as, for example, hydrogen carbonate and methylcarbonate anions,

carboxylate anions, such as, for example, salicylate, thiosalicylate, L-lactate, acetate, trifluroacetate, and formate anions,

chlorate anions,

cyanate anions, such as, for example, thiocyanate, dicyanamide, and tricyanomethane anions,

halide anions, such as, for example, fluoride, chloride, bromide, and iodide anions,

imide anions, such as, for example, imide, bis(fluoromethylsulfonyl)imide anions, and bis(trifluoromethylsulfonyl)imide anions,

nitrate anions,

phosphate anions, such as, for example, dihydrogen phosphate, hexafluorophosphate, di(trifluromethyl)tetrafluorophosphate, tris(trifluoromethyl)trifluorophosphate, tris(perfluoroalkyl)trifluorophosphate, tetra(trifluoromethyl)difluorophosphate, penta(trifluoromethyl)fluorphosphate, and hexa(trifluoromethyl)phosphate anions,

sulfate and sulfonate anions, such as, for example, trifluoromethanesulfonate, hydrogen sulfate, tosylate, (C₁-C₁₂)alkylsulfate, and (C₁-C₁₂)alkylsulfonate anions,

perfluoroalkyl β-diketonate anions, such as, for example, 6,6,7,7,8,8,8-heptafluoro-2,2-dimethyl-3,5-octanedionate, 1,1,1,5,5,5-hexafluoro-2,4-pentanedionate, and 4,4,4-trifluoro-1-(2-thienyl)-1,3-butanedionate anions,

fluorohydrogenate anions, such as, for example, poly(hydrogen fluoride) fluoride anions,

fluorometallate anions, such as, for example, oxopentafluorotungstan (VI) anions, and

polyoxometallate anions.

The ionic liquid may comprise a mixture of ionic liquid compounds and thus a mixture of two or more of such cations and/or two or more of such anions.

In one embodiment, the ionic liquid comprises one or more compounds have an imidazolium cation. In one embodiment, the imidazolium cation is selected from 1,3-dimethylimidazolium, 1-benzyl-3-methyl-imidazolium, 1-butyl-3-methyl-imidazolium, 1-ethyl-3-methyl-imidazolium, 1-hexyl-3-methyl-imidazolium, 1-methyl-3-propyl-imidazolium, 1-methyl-3-octyl-imidazolium, 1-methyl-3-tetradecyl-imidazolium, 1-methyl-3-phenylimidazolium, 1,2,3-trimethyl-imidazolium, 1,2-methyl-3-octyl-imidazolium, 1-butyl-2,3-dimethyl-imidazolium, 1-hexyl-2,3-methyl-imidazolium, and 1-(2-hydroxyethyl)-2,3-dimethyl-imidazolium cations.

In one embodiment, the ionic liquid comprises sulfonate anion, sulfate anion, carboxylate anion, bis(trifluoromethylsulfonyl)imide anion, nitrate anion, nitro anion, halogen anion, hexafluorophosphate (PF₆⁻) anion, or tetrafluoroborate anion.

In one embodiment, the ionic liquid comprises para-toluene sulfonate anion, (CF₃SO₃)⁻ anion, (CH₃CH₂CH₂CH₂SO₃)⁻ anion, (CHF₂CF₂CF₂ CF₂CH₂SO₃)⁻ anion, bis(trifluoromethylsulfonyl)imide anion, or tetrafluoroborate anion.

In one embodiment, the ionic liquid comprises a salt of an alkyl-, hydroxyalkyl- and/or aryl-substituted imidazolium cation and a tetrafluoroborate anion, such as, for example, 1,3-dimethyl-imidazolium tetrafluoroborate, 1-benzyl-3-methyl-imidazolium tetrafluoroborate, 1-butyl-3-methyl-imidazolium tetrafluoroborate, 1-ethyl-3-methyl-imidazolium tetrafluoroborate, 1-hexyl-3-methyl-imidazolium tetrafluoroborate, 1-methyl-3-propyl-imidazolium tetrafluoroborate, 1-methyl-3-octyl-imidazolium etrafluoroborate, 1-methyl-3-tetradecyl-imidazolium tetrafluoroborate, 1-methyl-3-phenyl-imidazolium tetrafluoroborate, 1,2,3-trimethyl-imidazolium tetrafluoroborate, 1,2-methyl-3-octyl-imidazolium tetrafluoroborate, 1-butyl-2,3-dimethyl-imidazolium tetrafluoroborate, 1-hexyl-2,3-methyl-imidazolium tetrafluoroborate, and 1-(2-hydroxyethyl)-2,3-dimethyl-imidazolium tetrafluoroborate, and mixtures thereof.

In one embodiment, the ionic liquid comprises a salt of an alkyl-, hydroxyalkyl- and/or aryl-substituted imidazolium cation and a bis(trifluoromethylsulfonyl)imide anion, such as, for example, 1,3-dimethyl-imidazolium bis(trifluoromethylsulfonyl)imide, 1-benzyl-3-methyl-imidazolium bis(trifluoromethylsulfonyl)imide, 1-butyl-3-methyl-imidazolium bis(trifluoromethylsulfonyl)imide, 1-ethyl-3-methyl-imidazolium bis(trifluoromethylsulfonyl)imide, 1-hexyl-3-methyl-imidazolium bis(trifluoromethylsulfonyl)imide, 1-methyl-3-propyl-imidazolium bis(trifluoromethylsulfonyl)imide, 1-methyl-3-octyl-imidazolium bis(trifluoromethylsulfonyl)imide, 1-methyl-3-tetradecyl-imidazolium bis(trifluoromethylsulfonyl)imide, 1-methyl-3-phenyl-imidazolium bis(trifluoromethylsulfonyl)imide, 1,2,3-trimethyl-imidazolium bis(trifluoromethylsulfonyl)imide, 1,2-methyl-3-octyl-imidazolium bis(trifluoromethylsulfonyl)imide, 1-butyl-2,3-dimethyl-imidazolium bis(trifluoromethylsulfonyl)imide, 1-hexyl-2,3-methyl-imidazolium bis(trifluoromethylsulfonyl)imide, and 1-(2-hydroxyethyl)-2,3-dimethyl-imidazolium bis(trifluoromethylsulfonyl)imide, and mixtures thereof.

In one embodiment, the ionic liquid can be an ionic compound that has a melting point of less than 25° C., a viscosity at 20° C. of less than or equal to about 100 centiPoise, and an ionic conductivity.

In one embodiment, the ionic liquid is an ionic compound that has a melting point of less than or equal to 25° C., such as, for example, 1-ethyl-3-methyl-imidazolium tetrachloroaluminate, 1-butyl-3-methyl-imidazolium tetrachloroaluminate, 1-ethyl-3-methyl-imidazolium acetate, 1-butyl-3-methyl-imidazolium acetate, 1-ethyl-3-methyl-imidazolium ethylsulfate, 1-butyl-3-methyl-imidazolium methylsulfate, 1-ethyl-3-methyl-imidazolium thiocyanate, 1-butyl-3-methyl-imidazolium thiocyanate, 1-ethyl-3-methyl-imidazolium bis(trifluoromethanesulfonyl)imide, 1-ethyl-3-methyl-imidazolium tetracyanoborate, 1-butyl-1-methyl-pyrrolidinium dicyanamide, 1-ethyl-3-methyl-imidazolium tetrafluoroborate, 1-ethyl-3-methyl-imidazolium trifluroacetate, 1-ethyl-3-methyl-imidazolium bis(fluoromethylsulfonyl)imide, and mixtures thereof.

In one embodiment, the ionic liquid comprises a salt of an alkyl-, hydroxyalkyl- and/or aryl-substituted imidazolium cation and a cyanate anion, such as, for example, 1,3-dimethyl-imidazolium dicyanate, 1-benzyl-3-methyl-imidazolium thiocyanate, 1-butyl-3-methyl-imidazolium tricyanomethane, 1-ethyl-3-methyl-imidazolium dicyanate, 1-hexyl-3-methyl-imidazolium thiocyanate, 1-methyl-3-propyl-imidazolium tricyanomethane, 1-methyl-3-octyl-imidazolium dicyanate, 1-methyl-3-tetradecyl-imidazolium thiocyanate, 1-methyl-3-phenyl-imidazolium dicyanate, 1,2,3-trimethyl-imidazolium thiocyanate, 1,2-methyl-3-octyl-imidazolium tricyanomethane, 1-butyl-2,3-dimethyl-imidazolium dicyanate, 1-hexyl-2,3-methyl-imidazolium thiocyanate, and 1-(2-hydroxyethyl)-2,3-dimethyl-imidazolium tricyanomethane, and mixtures thereof.

In one embodiment, the ionic liquid comprises one or more compounds comprising: (i) an imidazolium cation, and (ii) a tetracyanoborate anion.

In one embodiment, the ionic liquid comprises a salt of an alkyl-, hydroxyalkyl- and/or aryl-substituted imidazolium cation and a tetracyanoborate anion, such as, for example, 1,3-dimethyl-imidazolium tetracyanoborate, 1-benzyl-3-methyl-imidazolium tetracyanoborate, 1-butyl-3-methyl-imidazolium tetracyanoborate, 1-ethyl-3-methyl-imidazolium tetracyanoborate, 1-hexyl-3-methyl-imidazolium tetracyanoborate, 1-methyl-3-propyl-imidazolium tetracyanoborate, 1-methyl-3-octyl-imidazolium tetracyanoborate, 1-methyl-3-tetradecyl-imidazolium tetracyanoborate, 1-methyl-3-phenyl-imidazolium tetracyanoborate, 1,2,3-trimethyl-imidazolium tetracyanoborate, 1,2-methyl-3-octyl-imidazolium tetracyanoborate, 1-butyl-2,3-dimethyl-imidazolium tetracyanoborate, 1-hexyl-2,3-methyl-imidazolium tetracyanoborate, and 1-(2-hydroxyethyl)-2,3-dimethyl-imidazolium tetracyanoborate, and mixtures thereof.

In one embodiment, the ionic liquid comprises a salt of an alkyl-, hydroxyalkyl- and/or aryl-substituted imidazolium cation and a tetrakis-(p-(dimethyl(1H, 1H, 2H, 2H-perfluorooctyl)silyl)phenyl)borate anion, such as, for example, 1,3-dimethyl-imidazolium tetrakis-(p-(dimethyl(1H, 1H, 2H, 2H-perfluorooctyl)silyl)phenyl)borate, 1-benzyl-3-methyl-imidazolium tetrakis-(p-(dimethyl(1H, 1H, 2H, 2H-perfluorooctyl)silyl)phenyl)borate, 1-butyl-3-methyl-imidazolium tetrakis-(p-(dimethyl(1H, 1H, 2H, 2H-perfluorooctyl)silyl)phenyl)borate, 1-ethyl-3-methyl-imidazolium tetrakis-(p-(dimethyl(1H, 1H, 2H, 2H-perfluorooctyl)silyl)phenyl)borate, 1-hexyl-3-methyl-imidazolium tetrakis-(p-(dimethyl(1H, 1H, 2H, 2H-perfluorooctyl)silyl)phenyl)borate, 1-methyl-3-propyl-imidazolium tetrakis-(p-(dimethyl(1H, 1H, 2H, 2H-perfluorooctyl)silyl)phenyl)borate, 1-methyl-3-octyl-imidazolium tetrakis-(p-(dimethyl(1H, 1H, 2H, 2H-perfluorooctyl)silyl)phenyl)borate, 1-methyl-3-tetradecyl-imidazolium tetrakis-(p-(dimethyl(1H, 1H, 2H, 2H-perfluorooctyl)silyl)phenyl)borate, 1-methyl-3-phenyl-imidazolium tetrakis-(p-(dimethyl(1H, 1H, 2H, 2H-perfluorooctyl)silyl)phenyl)borate, 1,2,3-trimethyl-imidazolium tetrakis-(p-(dimethyl(1H, 1H, 2H, 2H-perfluorooctyl)silyl)phenyl)borate, 1,2-methyl-3-octyl-imidazolium tetrakis-(p-(dimethyl(1H, 1H, 2H, 2H-perfluorooctyl)silyl)phenyl)borate, 1-butyl-2,3-dimethyl-imidazolium tetrakis-(p-(dimethyl(1H, 1H, 2H, 2H-perfluorooctyl)silyl)phenyl)borate, 1-hexyl-2,3-methyl-imidazolium tetrakis-(p-(dimethyl(1H, 1H, 2H, 2H-perfluorooctyl)silyl)phenyl)borate, and 1-(2-hydroxyethyl)-2,3-dimethyl-imidazolium tetrakis-(p-(dimethyl(1H, 1H, 2H, 2H-perfluorooctyl)silyl)phenyl)borate, and mixtures thereof.

In one embodiment, the ionic liquid comprises a salt of an alkyl-, hydroxyalkyl- and/or aryl-substituted imidazolium cation and a hexafluorophosphate anion, such as, for example, 1,3-dimethyl-imidazolium hexfluorophosphate, 1-benzyl-3-methyl-imidazolium hexfluorophosphate, 1-butyl-3-methyl-imidazolium hexfluorophosphate, 1-ethyl-3-methyl-imidazolium hexfluorophosphate, 1-hexyl-3-methyl-imidazolium hexfluorophosphate, 1-methyl-3-propyl-imidazolium hexfluorophosphate, 1-methyl-3-octyl-imidazolium hexfluorophosphate, 1-methyl-3-tetradecyl-imidazolium hexfluorophosphate, 1-methyl-3-phenyl-imidazolium hexfluorophosphate, 1,2,3-trimethyl-imidazolium hexfluorophosphate, 1,2-methyl-3-octyl-imidazolium hexfluorophosphate, 1-butyl-2,3-dimethyl-imidazolium hexfluorophosphate, 1-hexyl-2,3-methyl-imidazolium hexfluorophosphate, and 1-(2-hydroxyethyl)-2,3-dimethyl-imidazolium hexfluorophosphate, and mixtures thereof.

The polymer complexes and/or polymer complex component of the electronic devices of the present invention may optionally further comprise one or more additional components, such as, for example one or more of polymers, dyes, coating aids, conductive particles, conductive inks, conductive pastes, charge transport materials, crosslinking agents, inorganic materials, such as, for example, zinc oxides, cerium oxides, titanium oxides, and combinations thereof.

In some embodiments, the polymer complexes and/or polymer complex component of the electronic devices of the present invention may optionally further comprise electrically conductive nanostructures. As used herein, the term “nanostructures” generally refers to nano-sized structures, at least one dimension of which is less than or equal to 500 nm, more typically, less than or equal to 250 nm, or less than or equal to 100 nm, or less than or equal to 50 nm, or less than or equal to 25 nm.

The electrically conductive nanostructures can be of any shape or geometry, more typically of anisotropic geometry. Typical anisotropic nanostructures include nanofibers, nanowires and nanotubes.

The electrically conductive nanostructures can be formed of any electrically conductive material, such as for example, metallic materials or non-metallic materials, such as carbon or graphite, and may comprise a mixture of nanostructures formed form different electrically conductive materials, such as a mixture of carbon fibers and silver nanowires.

In one embodiment, the polymer complexes and/or polymer complex component of the electronic devices of the present invention further comprise one or more metallic electrically conductive nanostructures, such as, for example, silver nanowires or silver nanotubes.

In one embodiment, the polymer complexes and/or polymer complex component of the electronic devices of the present invention may each optionally further comprise one or more electrically conductive additives, such as, for example, metal particles, including metal nanoparticles and metal nanowires, graphite particles, including graphite fibers, or carbon particles, including carbon fullerenes and carbon nanotubes, and as well as combinations of any such additives. Suitable fullerenes include for example, C60, C70, and C84 fullerenes, each of which may be derivatized, for example with a (3-methoxycarbonyl)-propyl-phenyl (“PCBM”) group, such as C60-PCBM, C-70-PCBM and C-84 PCBM derivatized fullerenes. Suitable carbon nanotubes include single wall carbon nanotubes having an armchair, zigzag or chiral structure, as well as multiwall carbon nanotubes, including double wall carbon nanotubes, and mixtures thereof.

In one embodiment, the polymer complexes and/or polymer complex component of the electronic devices of the present invention may each optionally comprise up to about 65 wt %, more typically from about 12 wt % to about 62 wt % carbon particles, more typically carbon nanotubes, and even more typically multi-wall carbon nanotubes, based on 100 wt % of the polymer complex.

The polymer complexes and/or polymer complex component of the electronic devices of the present invention are prepared from a polymer composition.

The polymer composition of the present invention comprises:

(a) at least one electrically conductive polymer,

(b) optionally one or more polymeric acid dopants,

(c) at least one ionic liquid,

(d) a liquid medium, and

(e) optionally one or more additives.

In an embodiment, the polymer composition of the present invention comprises, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer,
(b) from about 0 to about 10.0 w t%, more typically from about 0.1 to about 5.0 wt %, and even more typically from about 0.1 to about 3.0 wt % of polymeric acid dopant,
(c) from about 0.1 to about 70.0 wt %, more typically from about 0.1 to about 10.0 wt %, and even more typically from about 0.2 to about 5.0 wt % of ionic liquid,
(d) from about 1.0 to about 99.0 wt %, more typically from about 50.0 to about 99.0 wt %, and even more typically from about 80.0 to about 99.0 wt % of liquid medium.

In an embodiment of the polymer composition, the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment, the polymer composition of the present invention comprises, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer,
(b) from about 0 to about 10.0 wt %, more typically from about 0.1 to about 5.0 wt %, and even more typically from about 0.1 to about 3.0 wt % of polymeric acid dopant,
(c) from about 0.1 to about 70.0 wt %, more typically from about 0.1 to about 10.0 wt %, and even more typically from about 0.2 to about 5.0 wt % of ionic liquid,
(d) from about 1.0 to about 99.0 wt %, more typically from about 50.0 to about 99.0 wt %, and even more typically from about 80.0 to about 99.0 wt % of liquid medium, and
   the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment, the polymer composition of the present invention comprises, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer comprising monomeric units according to structure (I.a), more typically at least one polythiophene polymer comprising monomeric units according to structure (I.a), wherein Q is S, and even more typically of at least one electrically conductive polymer comprising poly(3,4-ethylenedioxythiophene),
(b) from about 0 to about 10.0 wt %, more typically from about 0.1 to about 5.0 wt %, and even more typically from about 0.1 to about 3.0 wt % of a water soluble polymeric acid dopant, more typically of at least one water soluble polymeric acid dopant comprising a poly(styrene sulfonic acid) dopant,
(c) from about 0.1 to about 70.0 wt %, more typically from about 0.1 to about 10.0 wt %, and even more typically from about 0.2 to about 5.0 wt % of ionic liquid comprising 1-ethyl-3-methyl-imidazolium tetracyanoborate,
(d) from about 1.0 to about 99.0 wt %, more typically from about 50.0 to about 99.0 wt %, and even more typically from about 80.0 to about 99.0 wt % of liquid medium, and
   the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment, the liquid medium is an aqueous medium that comprises water. In one embodiment, the liquid medium is an aqueous medium that consists essentially of water. In one embodiment, the liquid medium is an aqueous medium that consists of water. In one embodiment, the liquid medium is a non-aqueous medium that comprises one or more water miscible organic liquids. In one embodiment, the liquid medium is an aqueous medium that comprises water and, optionally, one or more water miscible organic liquids. Suitable water miscible organic liquids include polar aprotic organic solvents, such as, for example, dimethyl sulfoxide and dimethyl 2-methylglutarate (marketed as Rhodiasolv® IRIS), polar protic organic solvents, such as, for example, methanol, ethanol, propanol, ethylene glycol, and propylene glycol, and mixtures thereof. In one embodiment, the liquid medium comprises, based on 100 wt % of the liquid medium, from about 10 to 100 wt %, more typically from about 50 to 100 wt %, and even more typically, from about 90 to 100 wt %, water and from 0 to about 90 wt %, more typically from 0 pbw to about 50 wt %, and even more typically from 0 to about 10 wt % of one or more water miscible organic liquids.

In one embodiment, the liquid medium may be any liquid in which the electrically conductive polymer complex is soluble. In one embodiment, the liquid medium is a non-aqueous liquid medium and the electrically conductive polymer complex is soluble in the non-aqueous liquid medium. Suitable non-aqueous liquid media include organic liquids that have a boiling point of less than 120° C., more typically, less than or equal to about 100° C., selected, based on the choice of electrically conductive polymer complex, from non-polar organic solvents, such as hexanes, cyclohexane, benzene, toluene, chloroform, and diethyl ether, polar aprotic organic solvents, such as dichloromethane, ethyl acetate, acetone, and tetrahydrofuran, polar protic organic solvents, such as methanol, ethanol, and propanol, as well as mixtures of such solvents.

In one embodiment, the liquid medium may optionally further comprise, based on 100 wt % of the liquid medium, from greater than 0 to about 15 wt %, more typically from about 1 to about 10 wt %, of an organic liquid selected from high boiling polar organic liquids, typically having a boiling point of at least 120° C., more typically from diethylene glycol, meso-erythritol, 1,2,3,4,-tetrahydroxybutane, 2-nitroethanol, glycerol, sorbitol, dimethyl sulfoxide, tetrahydrofurane, dimethyl formamide, and mixtures thereof.

In one embodiment, the polymer complexes of the present invention comprise an interaction between the electrically conductive polymer and the ionic liquid. In one embodiment, the polymer complex, gel, and foam material have a porous structure, a high strength to weight and surface area to volume ratios, and high electrical conductivity. In one embodiment, the storage modulus, G′, of the polymer foam exceeds the loss modulus, G″, of the polymer complex at any angular frequency within a range of from about 0.01 to about 100 radians/second, as determined by dynamic oscillatory measurements using a dynamic mechanical analysis instrument, such as, for example, an AR-G2.

The polymer complex and/or polymer complex component of the electronic device of the present invention are made by forming a polymer composition by a process comprising contacting, in a liquid medium, an electrically conductive polymer and an ionic liquid.

In one embodiment, the polymer composition formed is a polymer composition described herein.

In one embodiment, the polymer complexes and/or the polymer complex component of the electronic device of the present invention may be a polymer gel.

In one embodiment, the polymer gel material and/or polymer gel component of the electronic device of the present invention are made by a process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer, and
(II) allowing the gel to form.

In one embodiment, the polymer gel material and/or polymer gel component of the electronic device of the present invention are made by a process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer, and
(II) allowing the gel to form,
(III) rinsing the gel formed in step (II) with a rinse liquid.

In one embodiment, the polymer complexes and/or the polymer complex component of the electronic device of the present invention may be a polymer foam.

In one embodiment, the polymer foams and/or polymer foam component of the electronic device of the present invention are made by a process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer,
(II) allowing the gel to form, and
(III) removing from the gel formed in step (II) any liquid remaining on or in the gel.

In one embodiment, the polymer foams and/or polymer foam component of the electronic device of the present invention are made by a process comprising:
(I) forming a polymer composition by a process comprising contacting, in a liquid medium:
   (i) an electrically conductive polymer,
   (ii) optionally one or more polymeric acid dopants,
   (iii) an ionic liquid,
   (iv) optionally one or more additives, wherein the amount of ionic liquid is effective to gel the electrically conductive polymer,
(II) allowing the gel to form,
(III) rinsing the gel formed in step (II) with a rinse liquid, and
(IV) removing from the gel rinsed in step (III) any liquid remaining on or in the gel.

In one embodiment, the electrically conductive polymer comprises monomeric units according to structure (I.a), more typically at least one polythiophene polymer comprising monomeric units according to structure (I.a), wherein Q is S, and even more typically of at least one electrically conductive polymer comprising poly(3,4-ethylenedioxythiophene); and the polymeric acid dopant comprises at least one water soluble polymeric acid dopant, more typically of at least one water soluble polymeric acid dopant comprising a poly(styrene sulfonic acid) dopant.

In one embodiment of the process, step (I) comprises: forming a polymer composition by a process comprising contacting, in a liquid medium, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer,
(b) from about 0 to about 10.0 wt %, more typically from about 0.1 to about 5.0 wt %, and even more typically from about 0.1 to about 3.0 wt % of polymeric acid dopant,
(c) from about 0.1 to about 70.0 wt %, more typically from about 0.1 to about 10.0 wt %, and even more typically from about 0.2 to about 5.0 wt % of ionic liquid,
(d) from about 1.0 to about 99.0 wt %, more typically from about 50.0 to about 99.0 wt %, and even more typically from about 80.0 to about 99.0 wt % of liquid medium.

In an embodiment, the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment of the process, step (I) comprises: forming a polymer composition by a process comprising contacting, in a liquid medium, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer,
(b) from about 0 to about 10.0 wt %, more typically from about 0.1 to about 5.0 wt %, and even more typically from about 0.1 to about 3.0 wt % of polymeric acid dopant,
(c) from about 0.1 to about 70.0 wt %, more typically from about 0.1 to about 10.0 wt %, and even more typically from about 0.2 to about 5.0 wt % of ionic liquid,
(d) from about 1.0 to about 99.0 wt %, more typically from about 50.0 to about 99.0 wt %, and even more typically from about 80.0 to about 99.0 wt % of liquid medium, and
   the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment of the process, step (I) comprises: forming a polymer composition by a process comprising contacting, in a liquid medium, based on 100 wt % of the polymer composition:
(a) from about 0.1 to about 10.0 wt %, more typically from about 0.1 to about 5.0 wt %, and even more typically from about 0.1 to about 3.0 wt % of electrically conductive polymer comprising monomeric units according to structure (I.a), more typically at least one polythiophene polymer comprising monomeric units according to structure (I.a), wherein Q is S, and even more typically of at least one electrically conductive polymer comprising poly(3,4-ethylenedioxythiophene),
(b) from about 0 to about 10.0 wt %, more typically from about 0.1 to about 5.0 wt %, and even more typically from about 0.1 to about 3.0 wt % of a water soluble polymeric acid dopant, more typically of at least one water soluble polymeric acid dopant comprising a poly(styrene sulfonic acid) dopant,
(c) from about 0.1 to about 70.0 wt %, more typically from about 0.1 to about 10.0 wt %, and even more typically from about 0.2 to about 5.0 wt % of ionic liquid comprising 1-ethyl-3-methyl-imidazolium tetracyanoborate,
(d) from about 1.0 to about 99.0 wt %, more typically from about 50.0 to about 99.0 wt %, and even more typically from about 80.0 to about 99.0 wt % of liquid medium, and
   the ratio of the total amount by weight of the ionic liquid to the total amount by weight of the electrically conductive polymer is typically from about 1:1 to about 45:1, more typically from 1.5:1 to 20:1, even more typically from about 2:1 to about 10:1.

In one embodiment, the electrically conductive polymer is soluble in a liquid medium and the ionic liquid is soluble in the liquid medium. In one embodiment, a dispersion of an electrically conductive polymer in a liquid medium is provided and the ionic liquid is soluble in the dispersion of the electrically conductive polymer and added to the liquid medium.

Once the electrically conductive polymer and ionic liquid are contacted in the liquid medium, the resulting polymer composition may optionally be mechanically stirred. The gelation occurs with or without stirring so long as an amount of ionic liquid effective to gel the electrically conductive polymer is used.

As used herein, the term “an amount of ionic liquid effective to gel the electrically conductive polymer” means the minimum amount of ionic liquid required to be combined with the electrically conductive polymer to bring about gelation of the electrically conductive polymer. The effective amount of ionic liquid required to gel the electrically conductive polymer will depend on the identity of the polymer and the ionic liquid, and may be determined by one of ordinary skill in the art as desired for a particular application, for example, by combining varying amounts of ionic liquid with electrically conductive polymer and observing the resulting polymer composition.

The formation of the polymer complexes of the present invention can be characterized as a two-step reaction. In the first step, some time after combining the ionic liquid and the electrically conductive polymer, the resulting composition becomes viscous. In the second step, the polymer composition visibly contracts in the liquid medium, giving rise to a gel surrounded by a liquid phase.

The polymeric complexes and/or polymer complex component of the electronic device of the present invention has a tridimensional structure and generally there is no limitation to each dimension of the polymer complexes. The appropriate dimensions will depend on the particular use or application of the polymer complexes. In an embodiment, the polymer complex has at least one dimension of at least 10 μm, typically at least 50 μm, more typically at least 100 μm, even more typically at least 500 μm. In an embodiment, the polymer complex has at least two dimensions of at least 10 μm, typically at least 50 μm, more typically at least 100 μm, even more typically at least 500 μm. In an embodiment, the polymer complex has three dimensions of at least 10 μm, typically at least 50 μm, more typically at least 100 μm, even more typically at least 500 μm.

The polymer complexes of the present invention may be molded into any desired shape. When the ionic liquid and electrically-conductive polymer are mixed, but before gelation occurs, the resulting mixture may be transferred to a mold of arbitrary shape, in which mold the gelation is allowed to proceed without disturbance to form a gel that takes on the shape of the mold. In one embodiment, the polymer complex is molded into a cylinder shape. In one embodiment, the polymer complex is molded into a parallelepiped shape. The mixture may also be deposited on a substrate to form three-dimensional flat structures. The substrate on which the polymer complex is formed may be rigid or flexible and may comprise, for example, a metal; a polymer, such as a plastic sheet; a glass, a paper, or a ceramic material.

The gelation time, i.e. the time between combining the ionic liquid with the electrically conductive polymer and formation of the viscous complex, may be varied. The gelation time is typically from about 1 minute to about 150 minutes. More typically, the gelation time is from about 2 minutes to about 120 minutes. Even more typically, the gelation time is from about 5 minutes to about 60 minutes.

The polymer gel that is formed by contacting the ionic liquid with the electrically conductive polymer may optionally be rinsed. In an embodiment, the polymer gel is rinsed with a rinse liquid. The rinse liquid may be any solvent in which the gel is not soluble. In an embodiment, the rinse liquid is an aqueous medium that comprises water. In one embodiment, the rinse liquid is an aqueous medium that consists essentially of water. In one embodiment, the rinse liquid is an aqueous medium that consists of water. In one embodiment, the rinse liquid is an aqueous medium that comprises water and, optionally, one or more water miscible organic liquids. Suitable water miscible organic liquids include polar aprotic organic solvents, such as, for example, dimethyl sulfoxide and dimethyl 2-methylglutarate (marketed as Rhodiasolv® IRIS), polar protic organic solvents, such as, for example, methanol, ethanol, propanol, ethylene glycol, and propylene glycol, and mixtures thereof. In one embodiment, the liquid medium comprises, based on 100 wt % of the liquid medium, from about 10 to 100 wt %, more typically from about 50 to 100 wt %, and even more typically, from about 90 to 100 wt %, water and from 0 to about 90 wt %, more typically from 0 pbw to about 50 wt %, and even more typically from 0 to about 10 wt % of one or more water miscible organic liquids.

The rinsing of the polymer gel that is formed by contacting the ionic liquid with the electrically conductive polymer may be achieved by any method known to those of ordinary skill in the art. For example, the gel may be immersed in an excess of rinse liquid. Typically, the amount of rinse liquid used is at least about 500 times the weight of the formed gel to be rinsed. More typically, the amount of rinse liquid used is from about 500 times to 2000 times the weight of the formed gel to be rinsed. Even more typically, the amount of rinse liquid used is from about 800 times to 1200 times the weight of the formed gel to be rinsed.

The rinse time, i.e. the amount of time the formed gel is in contact with the rinse liquid, may be varied. It was discovered that the amount of time the formed gel is in contact with the rinse liquid influences the conductivity of the final polymer foam material. Typically, the rinse time is from about 1 minute to about 24 hours. More typically, the rinse time is from about 2 minutes to about 120 minutes. Even more typically, the rinse time is from about 5 minutes to about 60 minutes.

The rinsing of the polymer gel that is formed by contacting the ionic liquid with the electrically conductive polymer may also be performed with or without agitation. Agitation may be accomplished using any method known to those of ordinary skill in the art, such as, for example, stirring using a magnetic stirrer, stirring at high speed using a vortex, or the like.

Any liquid, such as, for example, liquid medium, rinse liquid, or a mixture thereof, remaining on or in the polymer gel may be removed from the polymer gel. Any method known to those of ordinary skill in the art effective to remove any liquid from the polymer gel may be used, such as, for example, freeze-drying (lyophilization), heating under an infrared lamp, or the like.

The conductivity of the polymer complexes and/or polymer complex component of the electronic device of the present invention may be measured using methods known to those of ordinary skill in the art. For example, the conductivity of the polymer complex may be measured in a lengthwise manner. For a lengthwise measurement, a suitable apparatus is one that is composed of a rigid support on which two wires, serving as electrodes, are attached. The wires may be made from any electrically conductive material, such as, for example, copper, silver, aluminum, tin, and the like. The rigid support may be any material that is not electrically conductive, such as, for example, glass, plastic, hard rubber, and the like. The polymer complex to be analyzed is pressed against the electrodes, which are generally in contact with the ends of the polymer complex. For good contact, the complex is pressed against the electrodes by way of a clamp, which is insulated so as not to distort the measurement. The electrodes are then connected to the measuring device, such as, for example, a multimeter or an impedance analyzer. The conductivity of the polymer complex may also be measured along its thickness in which electrodes having a larger surface area are used. The polymer complex to be analyzed is “sandwiched” between the electrodes. For a measurement along the thickness of the polymer complex, a suitable apparatus is one that consists of two flat electrodes. Conductive paste, such as, for example, silver paste or conductive epoxy glue, may be used to conform to the rough surface of the polymer complex with the surface of the electrodes, thereby improving contact. Suitable electrodes include, but are not limited to, copper tape, silver tape, aluminum tape, and commercially-available platform electrodes. The polymer complex to be analyzed is then “sandwiched” between the electrodes. When conductive paste is used, it is essential to verify that the conductive paste does not bypass and short-circuit the sample foam. The electrodes are connected as usual to a suitable measuring device, such as, for example, a multimeter or impedance analyzer.

The conductivity of the polymer complexes may be determined according to the following equation:

ρ=L/RS

where p represents conductivity, in S/cm, L represents the distance between the electrodes, R represents the measured resistance, and S represents the cross-sectional area of polymer complex between the electrodes.

The polymer complexes and/or polymer complex component of the electronic device of the present invention have conductivity of from about 10 S/cm to about 120 S/cm. Typically, the polymer complexes and/or polymer complex component of the electronic device of the present invention have conductivity of from about 50 S/cm to about 110 S/cm. More typically, the polymer complexes and/or polymer complex component of the electronic device of the present invention have conductivity of from about 70 S/cm to about 100 S/cm.

The impedance of the polymer complexes and/or polymer complex component of the electronic device of the present invention may be analyzed using apparatuses and methods described herein or known to those of ordinary skill in the art. The impedance of the complex is the total opposition presented by the complex to the flow of alternating current, and is considered to be the sum effect of resistance and reactance, where the reactance may or may not change with frequency. In an embodiment, the polymer complex is purely resistive over a frequency range of from about 1 Hz to about 10⁵ Hz.

Various analytical techniques known to those of ordinary skill in the art may be used to verify the structure of the polymer complexes of the present invention. Vibrational spectroscopy, such as, for example, Raman spectroscopy, may be used to verify the molecular structure of the complexes. Microscopy techniques, such as, for example, electron microscopy and optical microscopy may also be utilized to verify the molecular structure of the complexes of the present invention. Whether a material has crystalline or amorphous structure may be determined by optical microscopy. In an embodiment, the polymer complexes of the present invention have an amorphous structure.

The polymer complexes and/or polymer complex component of the electronic device of the present invention exhibit a piezoresistive effect. The piezoresistive effect refers to a change in electrical resistivity with application of mechanical strain, such as, for example, the application of pressure. The piezoresistive effect is described by a gauge factor, generally denoted as K. The gauge factor (K) is given by the following equation:

K=(ΔR/R)(e/Δe)

where R is the electrical resistance, ΔR is the change in electrical resistance, e is the thickness of the foam, and Δe is the change in thickness. Generally, the determination of “e/Δe” is difficult. Fortunately, “e/Δe” is related to Young's modulus according to the following relation:

e/Δe=E/P

where E is Young's modulus and P is the applied pressure.

Any method known to those of ordinary skill in the art may be used to determine “ΔR/R” and “P”. For example, a suitable apparatus is one that consists of a weighing scale or balance and a rigid support on which the foam is placed. Two wires, serving as electrodes, are pressed against the ends of the polymer complex by a pressure, referred to here as contact pressure, provided by insulated clamps. The electrical circuit is completed by connection to a multimeter or an impedance analyzer. Additional supports placed underneath the rigid support may be used. The wires may be made from any electrically conductive material, such as, for example, copper, silver, aluminum, tin, and the like. The rigid support and additional supports may be any material that is not electrically conductive, such as, for example, glass, plastic, hard rubber, and the like.

A mass applied on the sample polymer complex allows for the determination of the pressure P, referred to here as applied pressure or piezoelectric-related pressure, which is related to the mass applied according to the equation:

P=mg/(surface area of application)

where m is the mass and g is the acceleration due to gravity. The values of R and ΔR are read from the electrical measuring device and P is calculated from the mass read from the balance or weighing scale.

Young's modulus (E) is given by the following equation:

E=σ/ε, ε=ΔI/I

where σ represents stress, in Pascals (Pa), and ε represents deformation, or strain, (ratio of change in length and length) of the foam. The stress and the deformation can each be determined using any apparatus known to those of ordinary skill in the art. By plotting the stress as a function of deformation, the slope of the resulting graph, or linear approximation thereof, gives an approximate value for Young's modulus. Any suitable apparatus known to those of ordinary skill in the art may be used to measure Young's moldulus. With Young's modulus of the foam known, the gauge factor K is determined by plotting “ΔR/R” as a function of “P/E”, wherein the slope of the graph gives the gauge factor.

The Young's modulus of the polymer complexes of the present invention is from about 0.01 GPa to about 0.2 GPa. Typically, the Young's modulus is from about 0.05 GPa to about 0.1 GPa.

The gauge factor of the polymer complexes and/or polymer complex component of the present invention is from about 5 to about 20. Typically, the gauge factor is from about 10 to about 18. More typically, the gauge factor is from about 12 to about 17.

The electronic device of the present invention may be any device that comprises one or more layers of semiconductor materials and makes use of the controlled motion of electrons or ions through such one or more layers, such as, for example:

a device that converts mechanical perturbation into a change in electrical conductivity, such as, for example, a piezoresistive device,

a device that converts electrical energy into radiation, such as, for example, a light-emitting diode, light emitting diode display, diode laser, a liquid crystal display, or lighting panel,

a device that detects signals through electronic processes, such as, for example, a photodetector, photoconductive cell, photoresistor, photoswitch, phototransistor, phototube, infrared (“IR”) detector, biosensor, or a touch screen display device,

a device that converts radiation into electrical energy, such as, for example, a photovoltaic device or solar cell,

a device that converts a temperature gradient (eg., heat flow) into electrical energy or converts electrical energy into a temperature gradient, such as a thermoelectric device, including, but not limited to, a thermoelectric cooler, a thermoelectric heater, or thermoelectric generator,

a device that stores and/or provide electrical, such as, for example, a battery, and

a device that includes one or more electronic components with one or more semiconductor layers, such as, for example, a transistor or diode.

In an embodiment, the electronic device is a piezoresistive device. Piezoresistive devices operate on the principle that one or more materials contained therein exhibit a change in electrical resistance when the one or more materials are mechanically strained, for example, by stretching or by compression. Piezoresistive devices include, but are not limited to, pressure sensors, tactile sensors, biosensors, and the like.

The present invention provides a piezoresistive device comprising:

(I) a polymer complex according to the present invention; and

(II) a first and second electrode.

In one embodiment, the piezoresistive device comprises:
(I) a polymer gel made by a process comprising:
   (a) forming a polymer composition by a process comprising contacting, in a liquid medium:
      (i) an electrically conductive polymer, and
      (ii) an ionic liquid, wherein the amount of ionic liquid is effective to gel the electrically conductive polymer, and
   (b) allowing the gel to form; and
(II) a first and second electrode.

In one embodiment, the piezoresistive device comprises:
(I) a polymer gel made by a process comprising:
   (a) forming a polymer composition by a process comprising contacting, in a liquid medium:
      (i) an electrically conductive polymer, and
      (ii) an ionic liquid, wherein the amount of ionic liquid is effective to gel the electrically conductive polymer,
   (b) allowing the gel to form, and
   (c) rinsing the gel formed in step (b) with a rinse liquid; and
(II) a first and second electrode.

In an embodiment, the piezoresistive device comprises:
(I) a polymer foam made according to a process comprising:
   (a) forming a polymer composition by a process comprising contacting, in a liquid medium:
      (i) an electrically conductive polymer, and
      (ii) an ionic liquid, wherein the amount of ionic liquid is effective to gel the electrically conductive polymer,
   (b) allowing the gel to form,
   (c) rinsing the gel formed in step (b) with a rinse liquid, and
   (d) removing the rinse liquid from the gel, thereby forming the polymer foam; and
(II) a first and second electrode.

The first and the second electrodes may be positioned such that they are physically isolated from one another but maintain electrical contact with the foam.

The first and second electrodes may be chosen from the same or different materials, as long as they are sufficiently electrically conductive.

The piezoresistive device of the present invention may further comprise an ohmmeter to measure the resistance between the first and second electrodes. For example, the electrical resistance of the foam in the piezoresistive device will change thereby eliciting a response from the coupled ohmmeter. This resistance measurement can be calibrated to the pressure applied and used to generate standardized data sets. These data sets could then be used to provide a direct readout of the pressure applied on the device.

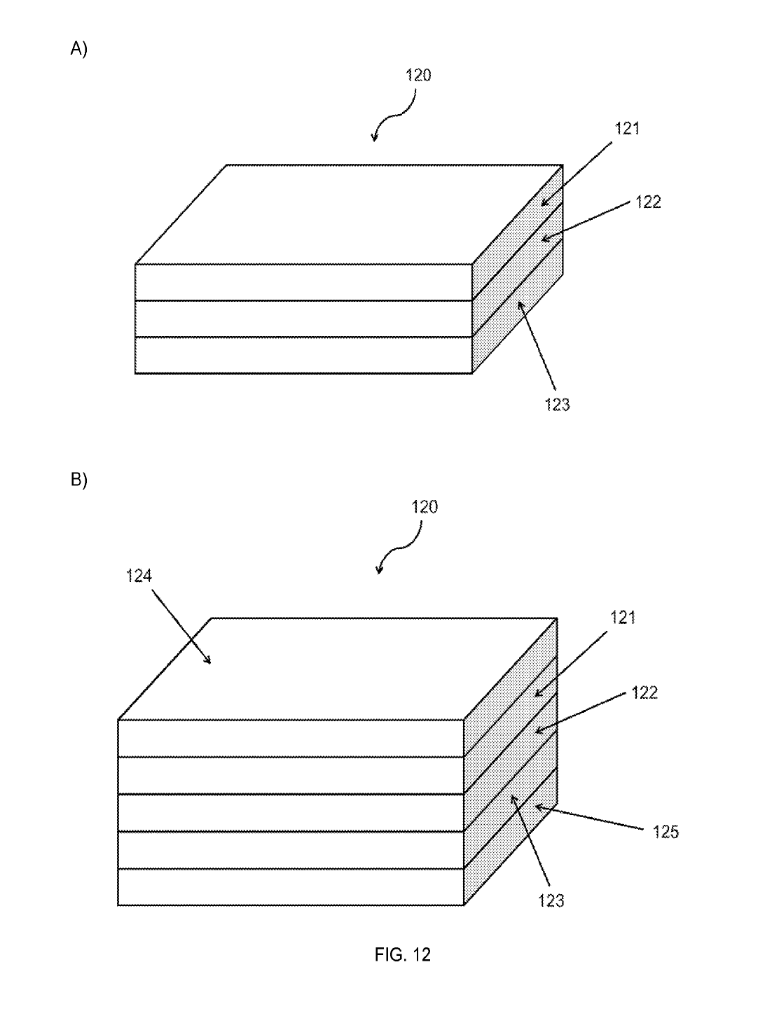

In an embodiment, the piezoresistive device of the present invention is a piezoresistive device 120, as shown in FIG. 12, having a piezoresistive layer 122, a first electrode 121, and a second electrode 123, wherein the piezoresistive layer 122 of the device is a polymer complex according to the present invention. The device 120 may further include a support or substrate adjacent to the first electrode 121 (shown as support layer 124 in FIG. 12B) and/or the second electrode 123 (shown as support layer 125 in FIG. 12B). The support or substrate can be flexible or rigid, organic or inorganic. Typically, the support or substrate is not electrically conductive. Suitable support materials include, for example, glass, ceramic, and plastic.

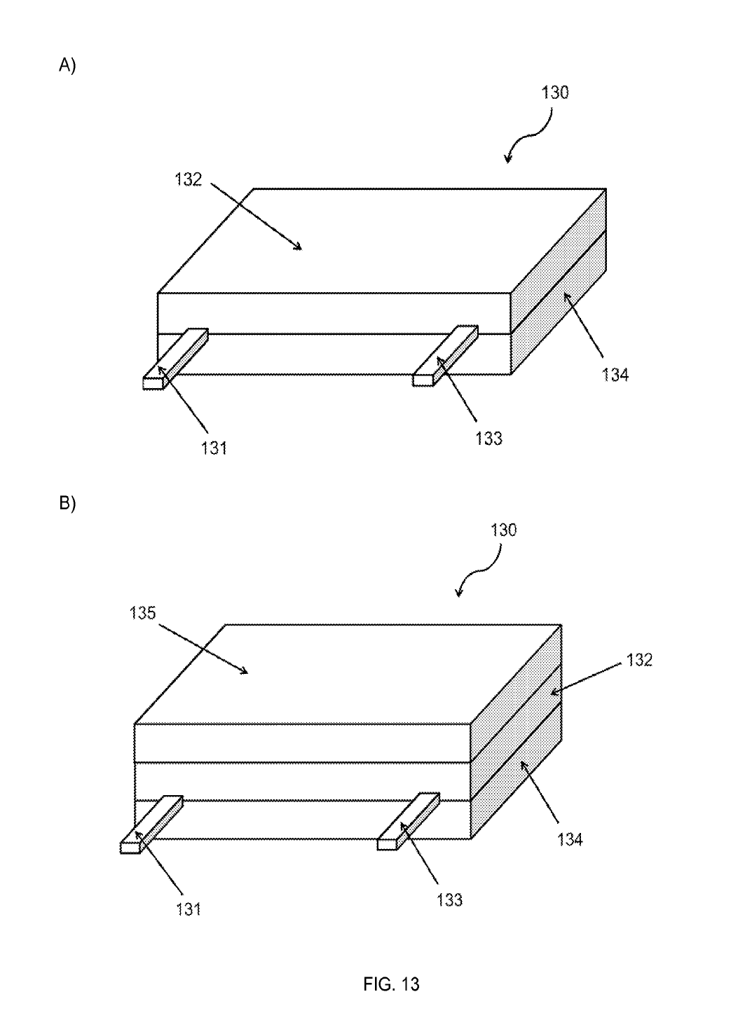

In an embodiment, the piezoresistive device of the present invention is a piezoresistive device 130, as shown in FIG. 13, having a piezoresistive layer 132, a first electrode 131, a second electrode 133, and a support layer 134, wherein the piezoresistive layer 132 of the device is a polymer complex according to the present invention. The device 130 may further include a support adjacent to the piezoresistive layer 132. The support or substrate can be flexible or rigid, organic or inorganic. Typically, the support or substrate is not electrically conductive. Suitable support materials include, for example, glass, ceramic, and plastic. The first and second electrodes 131 and 132 are compressed between the piezoresistive layer 132 and the support layer 134 such that the electrodes are in contact with the piezoresistive layer 132, but not with each other.

The piezoresistive device of the present invention is useful in a wide range of applications in areas such as, for example, biosensing, smart textiles, tactile sensing, and pressure sensing.

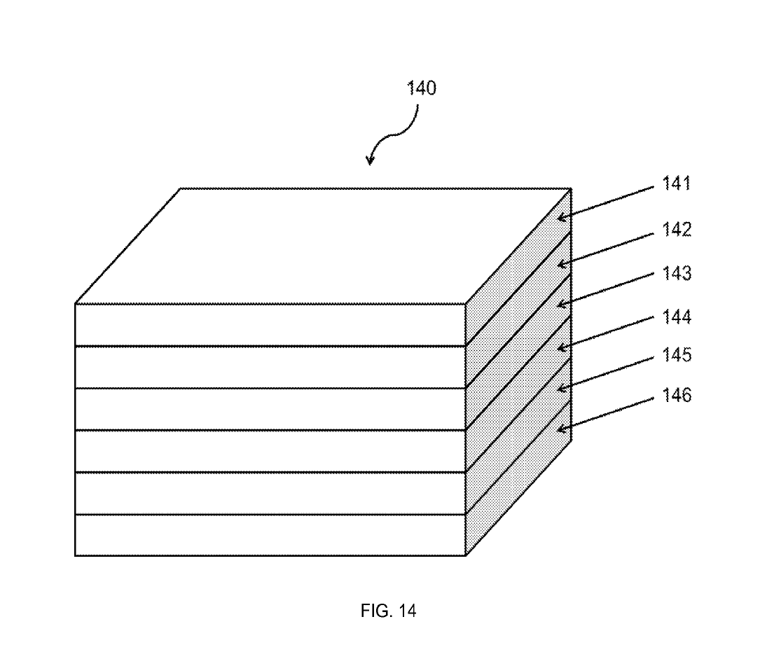

In one embodiment, the electronic device of the present invention is an electronic device 140, as shown in FIG. 14, having an anode layer 141, an electroactive layer 144, and a cathode layer 146 and optionally further having a buffer layer 142, hole transport layer 143, and/or electron injection/transport layer or confinement layer 145, wherein at least one of the layers of the device is a polymer complex according to the present invention. The device 140 may further include a support or substrate (not shown), that can be adjacent to the anode layer 141 or the cathode layer 146, more typically, adjacent to the anode layer 141. The support can be flexible or rigid, organic or inorganic. Suitable support materials include, for example, glass, ceramic, metal, and plastic films.

In some embodiments, optional hole transport layer 143 is present, either between anode layer 141 and electroactive layer 144, or, in those embodiments that comprise buffer layer 142, between buffer layer 142 and electroactive layer 144. Hole transport layer 143 may comprise one or more hole transporting molecules and/or polymers. Commonly used hole transporting molecules include, but are not limited to: 4,4′,4″-tris(N,N-diphenyl-amino)-triphenylamine, 4,4′,4″-tris(N-3-methylphenyl-N-phenyl-amino)-triphenylamine, N,N′-diphenyl-N,N′-bis(3-methylphenyl)-(1,1′-biphenyl)-4,4′-diamine, 1,1-bis((di-4-tolylamino)phenyl)cyclohexane, N,N′-bis(4-methylphenyl)-N,N′-bis(4-ethylphenyl)-(1,1′-(3,3′-dimethyl)biphenyl)-4,4′-diamine, tetrakis-(3-methylphenyl)-N,N,N′,N′-2,5-phenylenediamine, .alpha-phenyl-4-N,N-diphenylaminostyrene, p-(diethylamino)benzaldehyde diphenylhydrazone, triphenylamine, bis(4-(N,N-diethylamino)-2-methylphenyl)(4-methylphenyl)methane, 1-phenyl-3-(p-(diethylamino)styryl)-5-(p-(diethylamino)phenyl)pyrazoline, 1,2-trans-bis(9H-carbazol-9-yl)cyclobutane, N,N,N′,N′-tetrakis(4-methylphenyl)-(1,1′-biphenyl)-4,4′-diamine, N,N′-bis(naphthalen-1-yl)-N,N′-bis-(phenyl)benzidine, and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules, such as those mentioned above, into polymers such as polystyrene and polycarbonate.

The composition of electroactive layer 144 depends on the intended function of device 140, for example, electroactive layer 144 can be a light-emitting layer that is activated by an applied voltage (such as in a light-emitting diode or light-emitting electrochemical cell), or a layer of material that responds to radiant energy and generates a signal with or without an applied bias voltage (such as in a photodetector). In one embodiment, electroactive layer 144 comprises an organic electroluminescent (“EL”) material, such as, for example, electroluminescent small molecule organic compounds, electroluminescent metal complexes, and electroluminescent conjugated polymers, as well as mixtures thereof. Suitable EL small molecule organic compounds include, for example, pyrene, perylene, rubrene, and coumarin, as well as derivatives thereof and mixtures thereof. Suitable EL metal complexes include, for example, metal chelated oxinoid compounds, such as tris(8-hydroxyquinolate)aluminum, cyclo-metallated iridium and platinum electroluminescent compounds, such as complexes of iridium with phenylpyridine, phenylquinoline, or phenylpyrimidine ligands as disclosed in Petrov et al., U.S. Pat. No. 6,670,645, and organometallic complexes such as those described in, for example, Published PCT Applications WO 03/008424, as well as mixtures any of such EL metal complexes. Examples of EL conjugated polymers include, but are not limited to poly(phenylenevinylenes), polyfluorenes, poly(spirobifluorenes), polythiophenes, and poly(p-phenylenes), as well as copolymers thereof and mixtures thereof.

Optional layer 145 can function as an electron injection/transport layer and/or a confinement layer. More specifically, layer 145 may promote electron mobility and reduce the likelihood of a quenching reaction if layers 104 and 106 would otherwise be in direct contact. Examples of materials suitable for optional layer 105 include, for example, metal chelated oxinoid compounds, such as bis(2-methyl-8-quinolinolato)(para-phenyl-phenolato)aluminum(III) and tris(8-hydroxyquinolato)aluminum, tetrakis(8-hydroxyquinolinato)zirconium, azole compounds such as 2-(4-biphenylyl)-5-(4-t-butylphenyl)-1,3,4-oxadiazole, 3-(4-biphenylyl)-4-phenyl-5-(4-t-butylphenyl)-1,2,4-triazole, and 1,3,5-tri(phenyl-2-benzimidazole)benzene, quinoxaline derivatives such as 2,3-bis(4-fluorophenyl)quinoxaline, phenanthroline derivatives such as 9,10-diphenylphenanthroline and 2,9-dimethyl-4,7-diphenyl-1,10-phenanthroline, and as well as mixtures thereof. Alternatively, optional layer 145 may comprise an inorganic material, such as, for example, BaO, LiF, Li₂O.

Cathode layer 146 can be any metal or nonmetal having a lower work function than anode layer 141. In one embodiment, anode layer 141 has a work function of greater than or equal to about 4.4 eV and cathode layer 146 has a work function less than about 4.4 eV. Materials suitable for use as cathode layer 146 are known in the art and include, for example, alkali metals of Group 1, such as Li, Na, K, Rb, and Cs, Group 2 metals, such as, Mg, Ca, Ba, Group 12 metals, lanthanides such as Ce, Sm, and Eu, and actinides, as well as aluminum, indium, yttrium, and combinations of any such materials. Specific non-limiting examples of materials suitable for cathode layer 146 include, but are not limited to, Barium, Lithium, Cerium, Cesium, Europium, Rubidium, Yttrium, Magnesium, Samarium, and alloys and combinations thereof. Cathode layer 146 is typically formed by a chemical or physical vapor deposition process. In some embodiments, the cathode layer will be patterned, as discussed above in reference to the anode layer 141.

In one embodiment, an encapsulation layer (not shown) is deposited over cathode layer 146 to prevent entry of undesirable components, such as water and oxygen, into device 140. Such components can have a deleterious effect on electroactive layer 144. In one embodiment, the encapsulation layer is a barrier layer or film. In one embodiment, the encapsulation layer is a glass lid.

Though not shown in FIG. 14, it is understood that device 140 may comprise additional layers. Other layers that are known in the art or otherwise may be used. In addition, any of the above-described layers may comprise two or more sub-layers or may form a laminar structure. Alternatively, some or all of anode layer 141, buffer layer 142, hole transport layer 143, electron transport layer 145, cathode layer 146, and any additional layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill in the art.

The various layers of the electronic device can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing. Other layers in the device can be made of any materials which are known to be useful in such layers upon consideration of the function to be served by such layers.

In one embodiment of the device 140, the different layers have the following range of thicknesses:

anode layer 101, typically 500-5000 Angstroms (“Å”), more typically, 1000-2000 Å,

optional buffer layer 102: typically 50-2000 Å, more typically, 200-1000 Å,

optional hole transport layer 103: typically 50-2000 Å, more typically, 100-1000 Å,

photoactive layer 104: typically, 10-2000 Å, more typically, 100-1000 Å,

optional electron transport layer: typically 105, 50-2000 Å, more typically, 100-1000 Å, and

cathode layer 106: typically 200-10000 Å, more typically, 300-5000 Å. As is known in the art, the location of the electron-hole recombination zone in the device, and thus the emission spectrum of the device, can be affected by the relative thickness of each layer. The appropriate ratio of layer thicknesses will depend on the exact nature of the device and the materials used.

In one embodiment, the electronic device of the present invention, comprises:
(a) an anode or combined anode and buffer layer 141,
(b) a cathode layer 146,
(c) an electroactive layer 144, disposed between anode layer 141 and cathode layer 146,
(d) optionally, a buffer layer 142, typically disposed between anode layer 141 and electroactive layer 144,
(e) optionally, a hole transport layer 145, typically disposed between anode layer 141 and electroactive layer 144, or if buffer layer 142 is present, between buffer layer 142 and electroactive layer 144, and
(f) optionally an electron injection layer 145, typically disposed between electroactive layer 144 and cathode layer 146,
   wherein at least one of the layers of the device comprises a polymer complex according to the present invention.

In one embodiment, the electronic device of the present invention is a device for converting radiation into electrical energy, and comprises an anode 141 that comprises a polymer foam according to the present invention, a cathode layer 146, an electroactive layer 144 comprising a material that is capable of converting radiation into electrical energy, disposed between the anode layer 141 layer and the cathode layer 146, and optionally further comprising a buffer layer 142, a hole transport layer 143, and/or an electron injection layer 145.

In operation of one embodiment of device 140, such as a device for converting electrical energy into radiation, a voltage from an appropriate power supply (not depicted) is applied to device 140 so that an electrical current passes across the layers of the device 140 and electrons enter electroactive layer 144, and are converted into radiation, such as in the case of an electroluminescent device, a release of photon from electroactive layer 144.

In operation of another embodiment of device 140, such as device for converting radiation into electrical energy, device 140 is exposed to radiation impinges on electroactive layer 144, and is converted into a flow of electrical current across the layers of the device.

In one embodiment, the electronic device of the present invention is a thermoelectric device.

Generally, a thermoelectric device is a semiconductor device that converts a temperature difference into electricity, or vice versa. The thermoelectric device in accordance with the present invention comprises:
a first electrode,
at least one electrolyte, and
a second electrode;

wherein at least one of the first electrode, the at least one electrolyte, and the second electrode comprise the polymer complex described herein.

The first and second electrodes are in contact with the at least one electrolyte such that an applied temperature gradient over the at least one electrolyte or an applied voltage over the electrodes facilitate transport of ions to and/or from the electrodes via the at least one electrolyte, thereby facilitating a reduction-oxidation (redox) reaction at the electrodes.

In an embodiment, the first and/or the second electrode of the thermoelectric device comprise the polymer complex described herein. The first and/or second electrodes may comprise materials known to those skilled in the art to be useful in the electrodes of a thermoelectric device. Such materials can be used alone or in combination, as in mixtures or composites. Suitable electrode materials include, but are not limited to carbon materials with high specific surface area, for example activated carbon, carbon aerogels, carbon nanotubes, templated porous carbons, carbon nanofibers and graphene networks; and metal oxides such as, for example, RuO₂, IrO₂, MnO₂, NiO, Co₂O₃, SnO₂, V₂O₅, and MoO.

The at least one electrolyte can be any material capable of conducting ions from one electrode to the other opposite electrode in the thermoelectric device. In one embodiment, the at least one electrolyte comprises a polymer complex described herein.

Thermoelectricity allows for reversible interplay between heat flow (temperature gradient) and charge flow (electricity current). A thermoelectric effect may be obtained in various ways. A thermoelectric effect wherein a heat flow transport charge carriers, thus producing a voltage, is known as the Seebeck effect. A device that takes advantage of the Seebeck effect is used as an electric power source, which is generally known as a thermoelectric generator. Conversely, the reverse effect exists wherein an electrical current is used to generate heat flow (Peltier effect), thus, creating a temperature gradient. Thermoelectric coolers take advantage of the Peltier effect for pumping heat with electrical energy. A third kind of thermoelectric effect is the so called Thomson effect wherein a temperature gradient together with an electrical current cause heat to be generated and absorbed, respectively.

In an embodiment, the thermoelectric device described herein is a thermoelectric generator. In one embodiment, the thermoelectric device described herein is a thermoelectric cooler.

In one embodiment, the electronic device of the present invention is a battery, namely a battery cell.

Generally, a battery cell comprises a first electrode, at least one electrolyte, and a second electrode, wherein the first and second electrodes optionally contain a base metal or a material into/from which ions of a base metal can be inserted and desorbed.

The first electrode, the at least one electrolyte, and/or the second electrode may each comprise the polymer complex of the present invention.

In one embodiment, the first electrode is a cathode or cathode material. In one embodiment, the cathode or cathode material comprises a metal oxide, for example, lithium nickel oxide or a lithium metal oxide. In one embodiment, the cathode material utilized can comprise, but is not limited to, transition-metals, metal oxides, and the like. In another embodiment, the cathode material comprises at least aluminum, titanium, nickel, and/or alloys of these metals. In one embodiment, the cathode or cathode material comprises a polymer complex of the present invention.

In one embodiment, the second electrode is an anode or anode material. In one embodiment, the anode or anode material comprises, but is not limited to, graphite, copper, and the like. In one embodiment, the anode or anode material comprises a polymer complex of the present invention.

The at least one electrolyte can be any material capable of conducting ions from one electrode to the other opposite electrode in a battery cell. In one embodiment, the at least one electrolyte comprises a polymer complex of the present invention.

In one embodiment, the electronic device 140 is a battery cell comprising an anode 141, a cathode layer 146 and an electrolyte layer 144 disposed between the anode layer and cathode layer, wherein at least one of the anode layer, the cathode layer, and electrolyte layer comprises a polymer complex according to the present invention. The battery cell comprising an anode 141, a cathode layer 146 and an electrolyte layer 144 disposed between the anode layer and cathode layer, wherein at least one of the anode layer, the cathode layer, and electrolyte layer comprises a polymer complex according to the present invention may further comprise optional layers, the use of which may be determined by those having ordinary skill in the art.

The battery cell comprising an anode 141, a cathode layer 146 and an electrolyte layer 144 disposed between the anode layer and cathode layer, wherein at least one of the anode layer, the cathode layer, and electrolyte layer comprises a polymer complex according to the present invention may be made to have any arbitrary shape that is rigid, flexible, bendable, and/or twistable using methods known to a person of ordinary skill in the art. For example, the anode 141, the cathode 146, and the electrolyte layer 144 may be formed into a cable-type shape wherein the anode 141, cathode 146, the electrolyte layer 144, and any optional layers, are formed into concentric cylindrical layers in a cable-type shape that is flexible, bendable, and/or twistable. The shape of the battery cell may be adapted for any application, and the battery cell may be made to be wearable and/or waterproof.

The battery cell comprising an anode 141, a cathode layer 146 and an electrolyte layer 144 disposed between the anode layer and cathode layer, wherein at least one of the anode layer, the cathode layer, and electrolyte layer comprises a polymer complex according to the present invention may be part of a battery pack comprising one or more battery cells. The battery pack may be made to have any arbitrary shape that is rigid, flexible, bendable, and/or twistable using methods known to a person of ordinary skill in the art.

The present invention is further illustrated by the following non-limiting examples.

General Procedure for Preparing Inventive Polymer Complexes

5 g PEDOT: PSS (1.3% PEDOT:PSS aqueous dispersion; Clevios PH1000, sold by Heraeus) was added into a reaction container followed by addition of various amounts of ionic liquid [0.05 to 0.15g of 1-ethyl-3-methylimidazolium tetracyanoborate (EMIM TCB, sold by Merck)]. The dispersion was then stirred using a vortex, such as a Vortex-Genie 2 at 7000 rev/min. Stirring was stopped 15 seconds after the addition of the ionic liquid and the resulting composition was left undisturbed to form a gel. The composition gelled between 5 to 60 minutes. The gel formed was then dried.

Optionally, following gelation but before drying, the gel was removed and washed. During washing, it was optionally stirred by a low speed magnetic agitator to allow for a good washing. The gel was washed for 5 minutes to 24 hours. Following this optional step, the gel was dried.

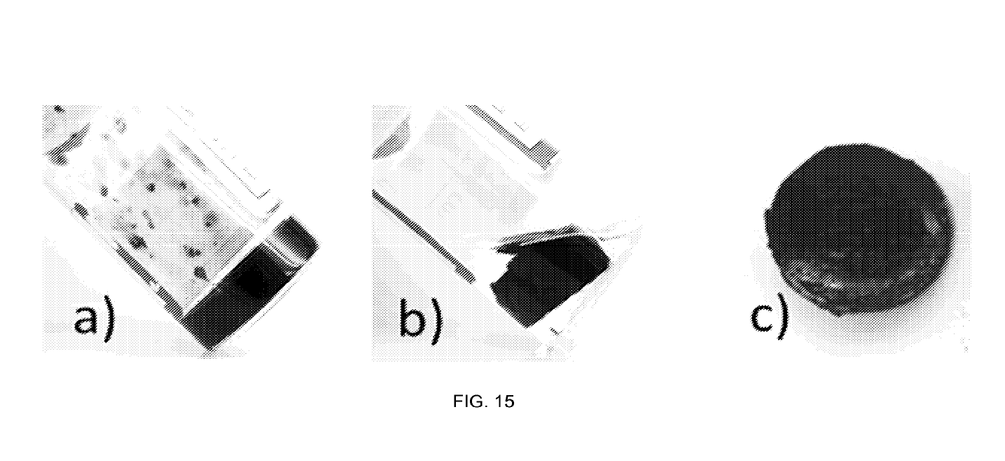

FIG. 15a shows generally a composition comprising PEDOT:PSS and ionic liquid. FIG. 15b shows the polymer gel formed after 1 hour. FIG. 15c shows the inventive foam prepared by removing remaining liquid by freeze-drying.

### EXAMPLE 1a

Foam materials were made according to the general procedure described. 5 g PEDOT: PSS dispersion was added into a vial followed by addition of 0.05 to 0.15g of EMIM TCB. The dispersion was then stirred using a vortex at 7000 rev/min. Stirring was stopped 15 s after the addition of the ionic liquid and the resulting composition was left on the bench to form a gel. A gel formed between 5 to 60 minutes. After gelation, the resulting gel was removed and put in 1 L of water to be washed. The gel was washed from 5 min to 24 hours. The gel was dried using a freeze drier to allow for the formation of the foam.

### EXAMPLE 1b

Foam polymer materials were made according to the general procedure described and 0.15 g of EMIM TCB was used. The mixture was deposited in a mold or on a substrate. The mixture was allowed to sit for 60 to 120 minutes, during which gelation and subsequent formation of a gel occurred. The polymer gel was then washed by immersing the mold containing the gel in about 1 L of water, which was optionally stirred by a low-speed magnetic agitator to wash the gel. The gel was washed for 60 to 120 minutes. Following the washing step, the gel was dried under an infrared lamp for 60 minutes at 100 ° C. to form the foam.

### EXAMPLE 2

### Characterization

Thickness and Texture

The thickness and texture of the inventive foams depended on the technique of rinsing used.

A significant reduction in the thickness of the rinsed foams relative to the unrinsed foams (for the same initial volume and the same mold) was observed. There is a general tendency for the thickness to decrease when the effectiveness of the rinsing step was increased (rinsing with agitation considered more effective than rinsing without agitation), as shown in Table 1 below. For example, regardless of gelation time, as the effectiveness of the rinsing is increased, the thickness of the foam decreased.

TABLE 1

| | Gelation time | | |
|---|---|---|---|
| Rinsing | 60 min | 90 min | 120 min |
| No rinsing | 264 μm | 201 μm | 220 μm |
| 60 min without agitation | 63 μm | 58 μm | 50 μm |
| 60 min with agitation | 44 μm | 49 μm | 36 μm |

Optical Microscopy

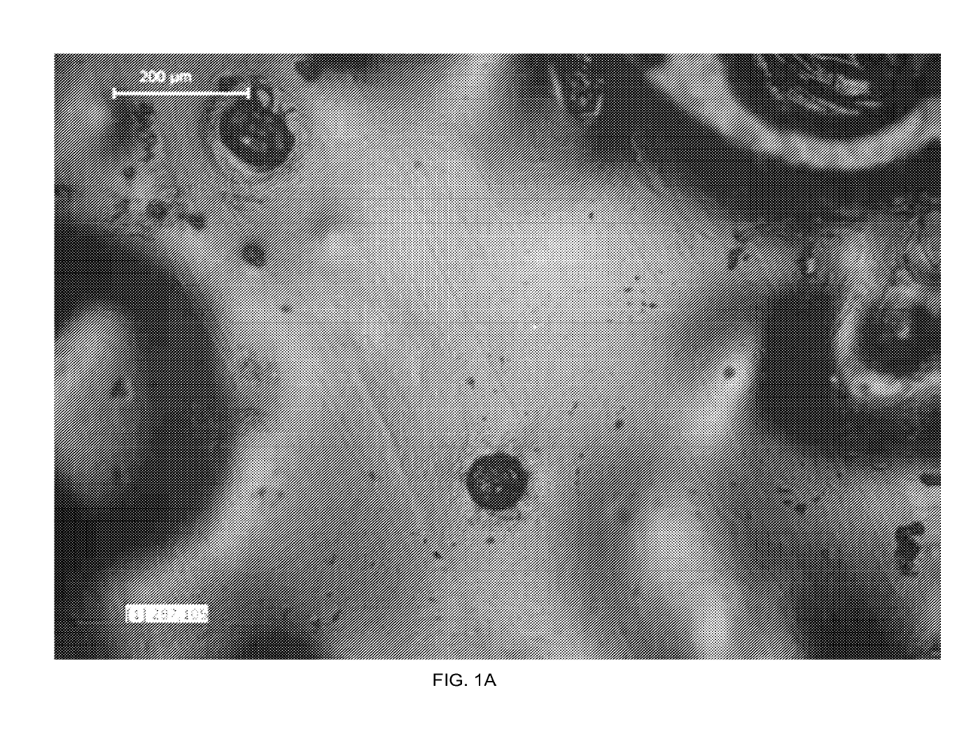

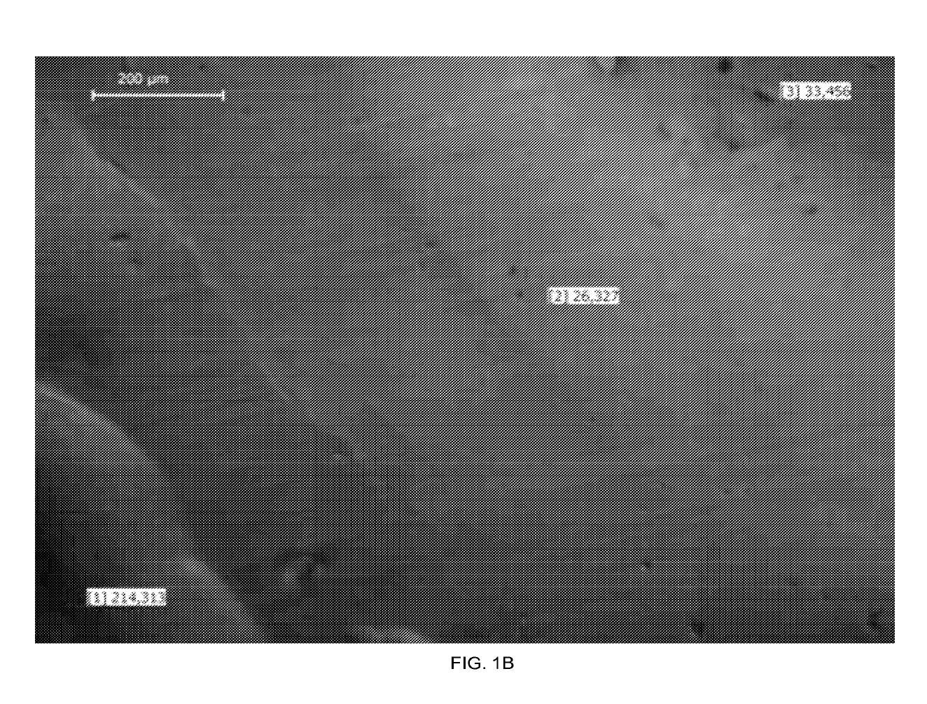

The inventive foams were observed with an optical microscope using reflected light as the foams are generally dark in color and opaque. The optical micrographs of the foams are shown in FIGS. 1A and 1B.

Moreover, reflective optical microscopy in conjunction with the use of polarized light, allows for the determination of whether the material under study is crystalline or amorphous. The observation in polarized light shows that the inventive foams studied have an amorphous structure. This is consistent with the fact that no constraint (eg, flow) was applied to the fluid in the gelation samples.

Raman Spectroscopy

The inventive foams were characterized by Raman spectroscopy, a method of nondestructive analysis based on inelastic Raman scattering. Raman spectroscopy provides information that is probative of the nature and strength of the chemical bonds in a material.

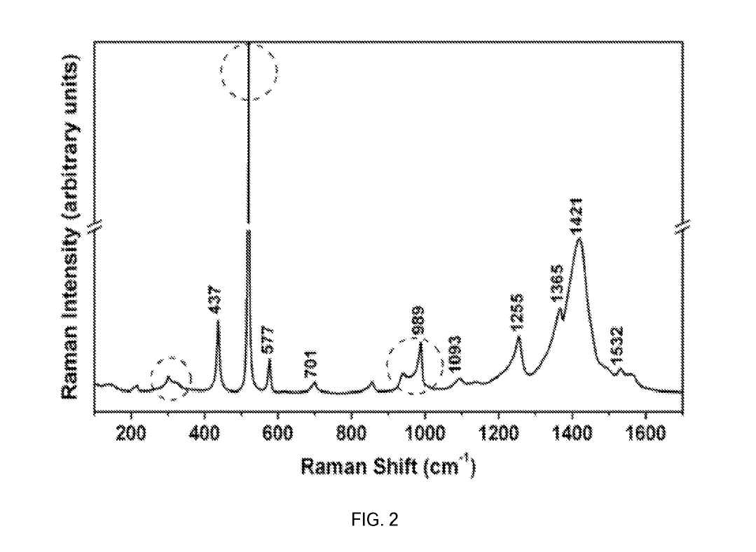

A study of PEDOT: PSS films that do not contain ionic liquid has previously been conducted using Raman spectroscopy and is described in Antje Schaarschmidt, Abdiaziz A Farah, Arun Aby, et al. Influence of Nonadiabatic Annealing on the Morphology and Molecular Structure of PEDOT-PSS Films. Journal of Physical Chemistry B, 113:9352-9355, 2009. The publication describes the Raman spectrum of PEDOT: PSS. The Raman spectrum of PEDOT:PSS has a number of characteristic vibration frequencies as shown in FIG. 2, corresponding to the connections summarized in Table 2 below.

TABLE 2
1563 and 1532 cm⁻¹ for the asymmetric stretching vibration of C_{α} = C_{β}
1421 cm⁻¹ for the symmetric stretching vibration of C_{α} = C_{β}
1365 cm⁻¹ to the stretching vibration of C_{β}-C_{β},
1255 cm⁻¹ for the stretching vibration of C_{α}-C_{α} between cycles
1093 cm⁻¹ to the deformation vibration of C—O—C
989 and 577 cm⁻¹ for the bending vibration of oxyethylene cycle
701 cm⁻¹ for the symmetrical deformation of C—S—C
437 cm⁻¹ for SO₂ group of PSS

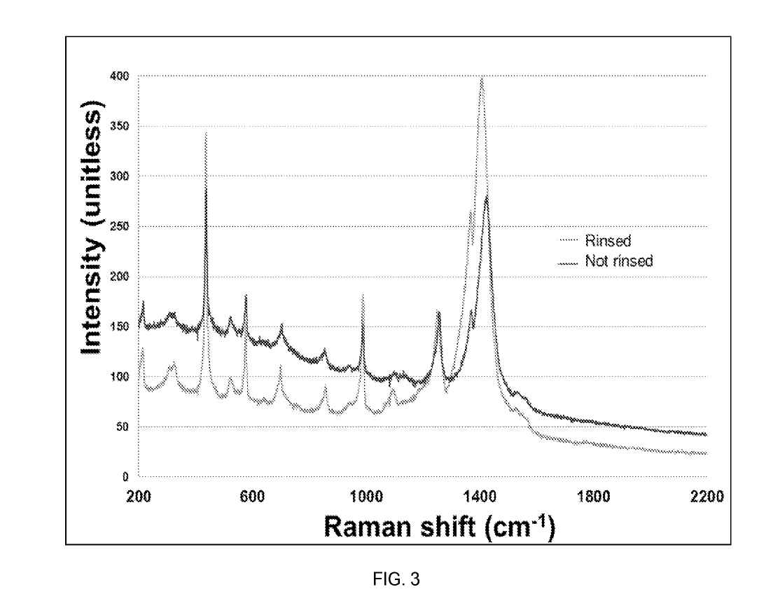

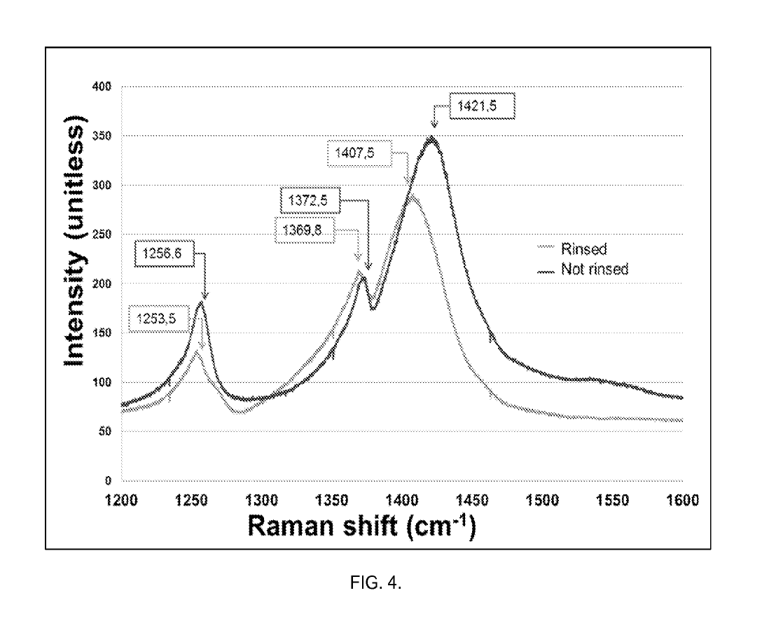

These characteristic vibration frequencies are mostly preserved in the Raman spectrum of inventive foams. The Raman spectra of the inventive foams are shown in FIGS. 3 and 4. Indeed, the spectra show the same general shape and roughly the same characteristic frequencies.

However, closer inspection revealed differences between polymer complexes that were rinsed and those that were not. For the symmetric stretching vibration of C_{α}=C_{β}, a maximum corresponding to 1421.5 cm⁻¹ in the case where the gel was not rinsed was observed whereas a Raman shift of 1407.5 cm⁻¹ was observed where the foam was rinsed (see FIG. 4), indicating weakening of the associated bond. The maximum variation in frequency observed between samples of identical gelation time but different method of rinsing was about 15 cm⁻¹, with a shift towards lower frequencies for foams that were rinsed. Frequency variations with respect to the peaks corresponding to the stretching vibration of C_{β}-C_{β} and the stretching vibration of C_{α}-C_{α} between cycles (up to 5 cm⁻¹) were also observed. These variations are suggestive of a weakening of the bonds in the foam due to rinsing.

Without wishing to be bound by theory, a possible explanation for these results may be that there is a change in the pi-stacking interactions between chains of PEDOT and PSS chains in the inventive foams that are rinsed, which lead to changes in the strength of the intramolecular bonds.

Again, without wishing to be bound by theory, the modification of the strength of the bond (and thus the pi-stacking) may be due to the elimination of the PSS of the foam during rinsing. To test this hypothesis, the areas of the peak at 437 cm⁻¹ (characteristic of the group SO₂, which is due only to the presence of PSS) for a rinsed foam and an unrinsed foam were compared. The ratio of these areas directly relate to the ratio of PSS in the foams. It was found that the ratio was small. The result suggests that the modification in the strength of the bonds is not likely due to the elimination of PSS from the foam. It is more likely that rinsing induces a molecular rearrangement within the foam.

Electron Microscopy

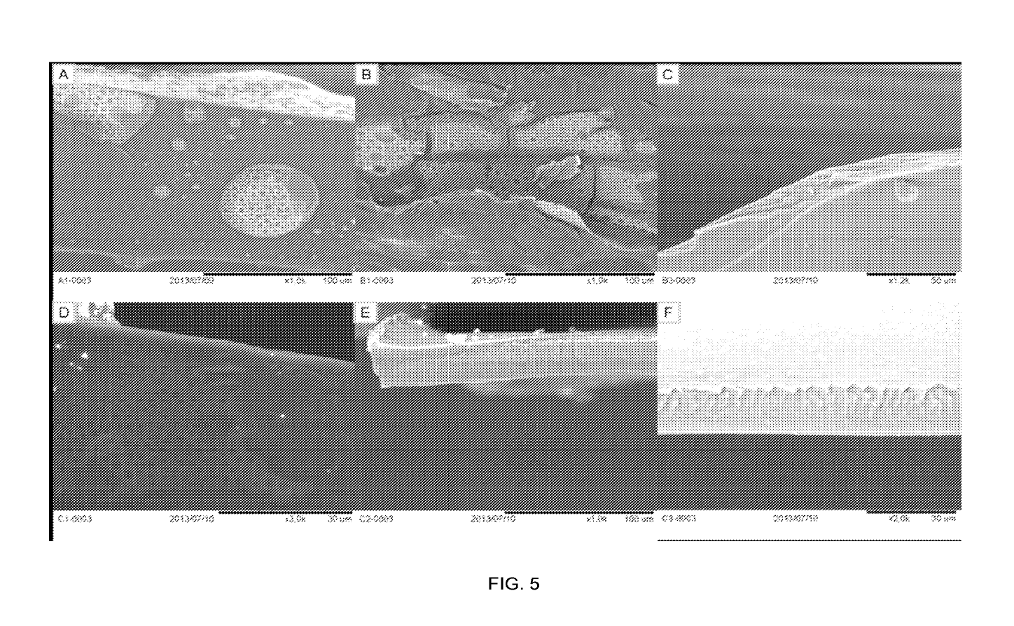

The inventive foams were analyzed using a scanning electron microscope (SEM), which allows for observation of the structure of the foams with a magnification of up to 10000×. The SEM images obtained are shown in FIG. 5.

Examination of the inventive foams revealed that only the unwashed foams have pores. In addition, the average size of these pores seems to decrease when the rinse time is increased. Looking successively at FIG. 5A, 5B, then 5D, corresponding to 60 minutes, 90 minutes and 120 minutes of reaction, respectively, a decrease in pore size can be seen. On the other hand, it was observed that foams that were rinsed and then dried by lyophilization exhibited pores ranging in size from a dozen to a hundred micrometers (not shown).

A small number of rinsed foams seem to have a lamellar structure (see FIG. 5C), but it is neither systematic nor related to other properties (conductivity, strength of the bonds, etc.).

### EXAMPLE 3

### Conductivity

The conductivity of the inventive foams was measured along the length of the foam and along the thickness of the foam.

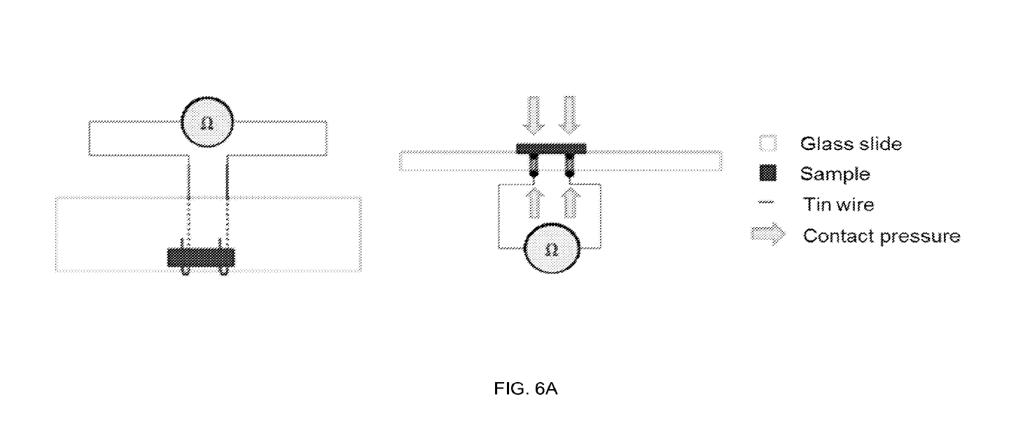

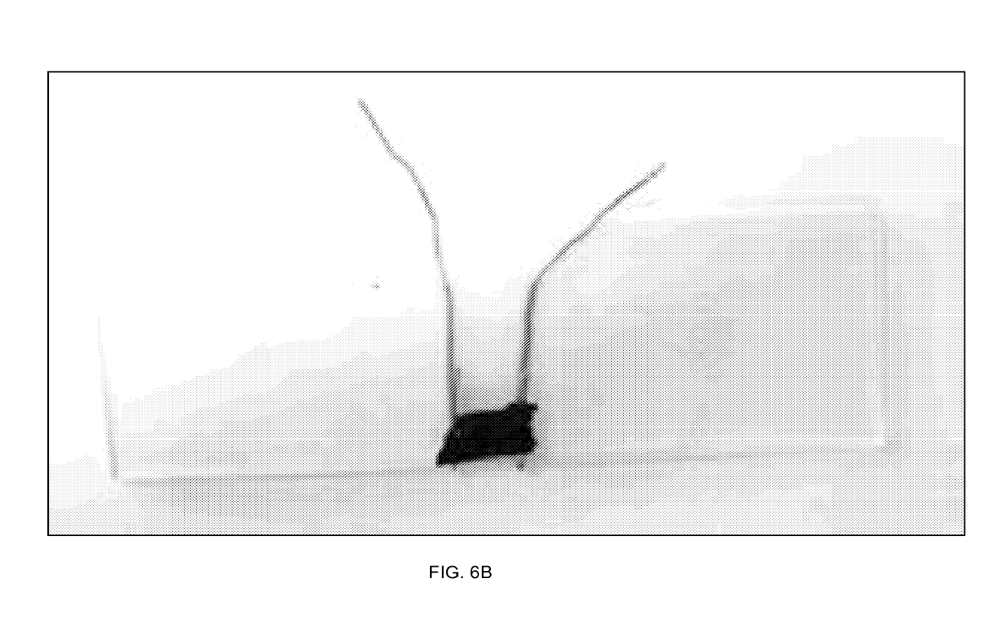

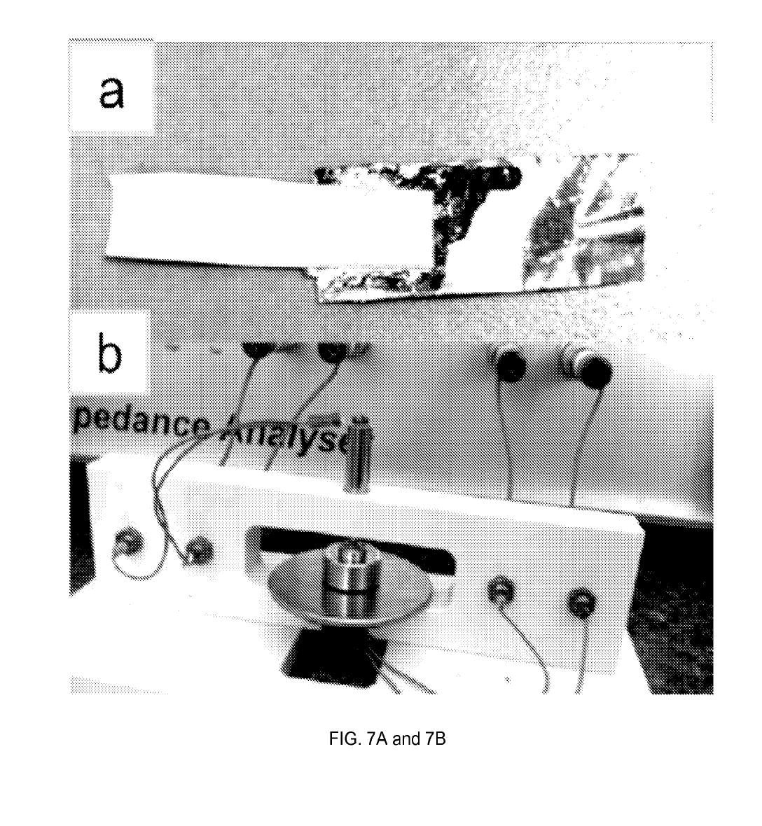

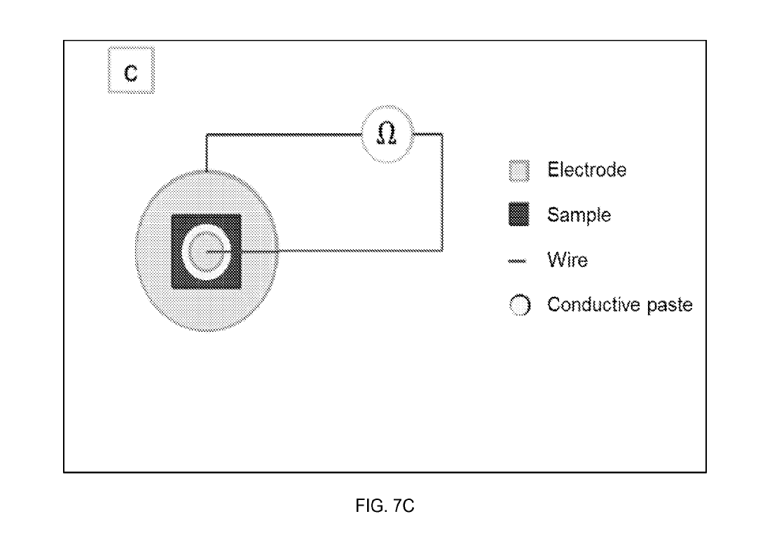

For the through-length measurement, the apparatus used is depicted schematically in FIG. 6A. Briefly, the apparatus was composed of a glass slide on which two wires serving as electrodes were attached. The foam to be analyzed was then pressed against the electrodes by an insulated clamp. A photograph of the foam and glass slide is shown in FIG. 6B without clamps. The electrodes were then connected to a multimeter or impedance analyzer. For the through-thickness measurement, the apparatus depicted in FIG. 7 was used. The apparatus consisted of two flat electrodes (either copper tape as shown in FIG. 7A or electrode setup shown in FIG. 7B) on which conductive silver paste was used to improve contact between the foam to be analyzed and the electrodes. With the flat electrodes, it is essential to verify that the silver paste does not short-circuit the electrodes.

The conductivities of the inventive foam materials vary depending on the gelation time, whether the foam is rinsed or unrinsed, and, if rinsed, the presence of absence of agitation, and rinse time, as shown in Table 3 below. The conductivities summarized in Table 3 were determined by lengthwise measurement.

TABLE 3

| | Gelation time | | |
|---|---|---|---|
| Rinsing | 60 min | 90 min | 120 min |
| No rinsing | 16 S · cm⁻¹ | 29 S · cm⁻¹ | 24 S · cm⁻¹ |
| 60 min without agitation | 78 S · cm⁻¹ | 99 S · cm⁻¹ | 97 S · cm⁻¹ |
| 60 min with agitation | 21 S · cm⁻¹ | 14 S · cm⁻¹ | 30 S · cm⁻¹ |

The data summarized in Table 2 shows that depending on the chosen preparation, conductivities on the order of 10² S·cm⁻¹ can be achieved. This value is much higher than those obtained so far for organic conductive materials having a thickness in excess of ten microns. To date, the highest conductivity reported in the literature for PEDOT:PSS-based materials is that of aerogels prepared using supercritical CO₂ drying and is of the order of 10⁻¹ S·cm⁻¹ (see Xuetong Zhang, Dongwu Chang, Jiren Liu, et al. Conducting polymer aerogels from Supercritical CO₂ drying PEDOT-PSS hydrogels. J. Mater. Chem., 20:5080-5085, 2010). Additionally, the highest conductivity reported in the literature for polyaniline-based materials, is 1 S·cm⁻¹ when dodecylbenzenesulfonic acid (DBSA) is used as counter ion (see Terhi Vikki, Janne Ruokolainen, Olli T. Ikkala, et al. Thermoreversible gels of polyaniline: Viscoelastic and electrical evidence on fusible network structures. Macromolecules, 30(14):4064-4072, 1997). These literature values are far below the conductivity values obtained with the inventive foam materials.

According to Table 2, it is clear that regardless of gelation time, the most conductive foams are those having been rinsed for 60 minutes without agitation. Without wishing to be bound by theory, it is believed that the greater thickness of the unrinsed foams may be due to the presence of entrained ionic liquid and that the reduction of thickness is due to the removal of some ionic liquid entrained in the foam during formation.

The inventive foams that were rinsed with agitation were found to have a higher resistance (lower conductivity) compared to those rinsed without agitation for a comparable thickness. Again, without wishing to be bound by theory, it is believed that agitation allows for more effective rinsing, which, therefore, eliminates an increased amount of ionic liquid. It is believed that removal of too much ionic liquid results in a modification of the molecular arrangement of the PEDOT chains (this is expressed by the changes in the Raman spectrum described herein and shown in FIGS. 3 and 4), which may lead to a decrease in conductivity.

Conductivities calculated from data acquired by the through-thickness measurements provided values ranging from 0.03 to 0.47 S·cm⁻¹, which are two to three orders of magnitude lower than the values obtained in the lengthwise measurements (see Table 3). Anisotropy in the foams may be possible.

Even though the through-thickness measurements proved to be less reliable than the lengthwise measurements, the through-thickness measurement was advantageous in determining the impedance of the foams as a function of alternating current frequency.

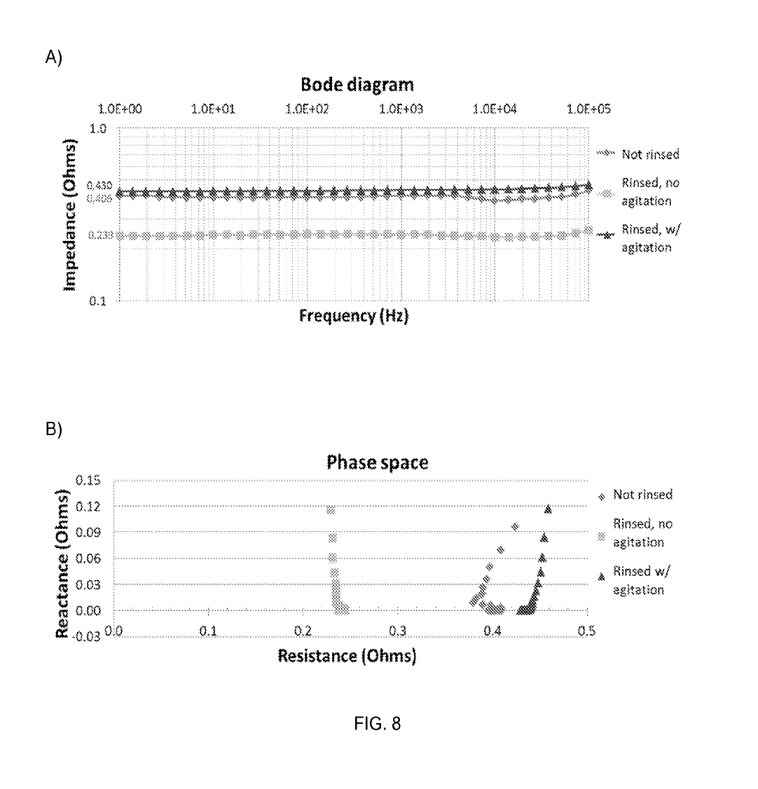

Using the through-thickness apparatus, the impedance of the inventive foams was analyzed as a function of frequency. The frequency range varied from 1 Hz to 10⁶ Hz. The impedance is characterized by its magnitude and phase, as shown in FIGS. 8A and 8B, respectively.

The magnitude of the impedance changes very little as a function of the frequency. In terms of phase, the increase in reactance at very high frequency was due solely to the measuring device used, which overestimates the reactance. Neglecting the overestimation of reactance by the impedance analyzer, it was observed in the phase space that the behavior of the foams is purely resistive (i.e. reactance tends to zero for a non-zero resistance) over a wide frequency range (1 to 10⁵ Hz).

### EXAMPLE b 4

### Piezoresistive Effect

The piezoresistive effect of the inventive foams was determined.

As discussed herein, the piezoresistive effect is described by a gauge factor K. The gauge factor (K) is given by the following equation:

K=(ΔR/R)(e/Δe)

where R is the electrical resistance, ΔR is the change in electrical resistance, e is the thickness of the foam, and Δe is the change in thickness. As a practical matter, the determination of “e/Δe” is difficult. Fortunately, “e/Δe” is related to Young's modulus according to the following relation:

e/Δe=E/P

where E is Young's modulus and P is the applied pressure. Thus, it was possible to determine the gauge factor of the foams be determining R, ΔR, E, and P.

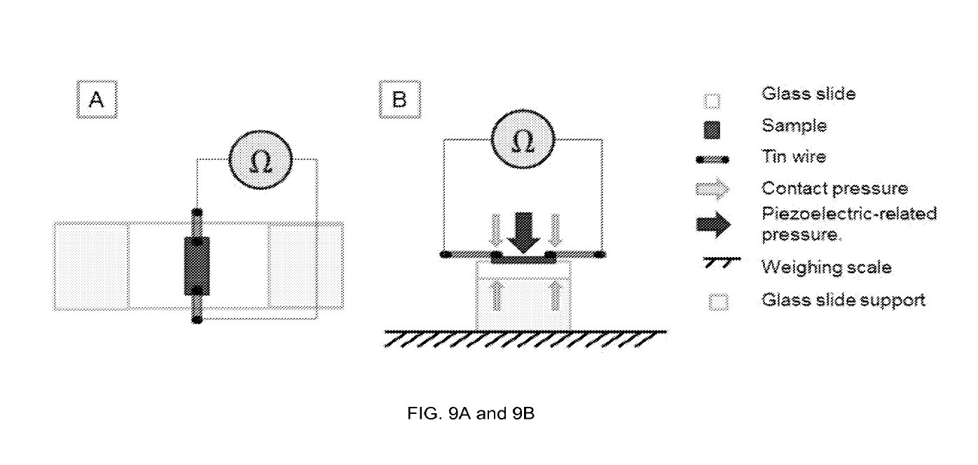

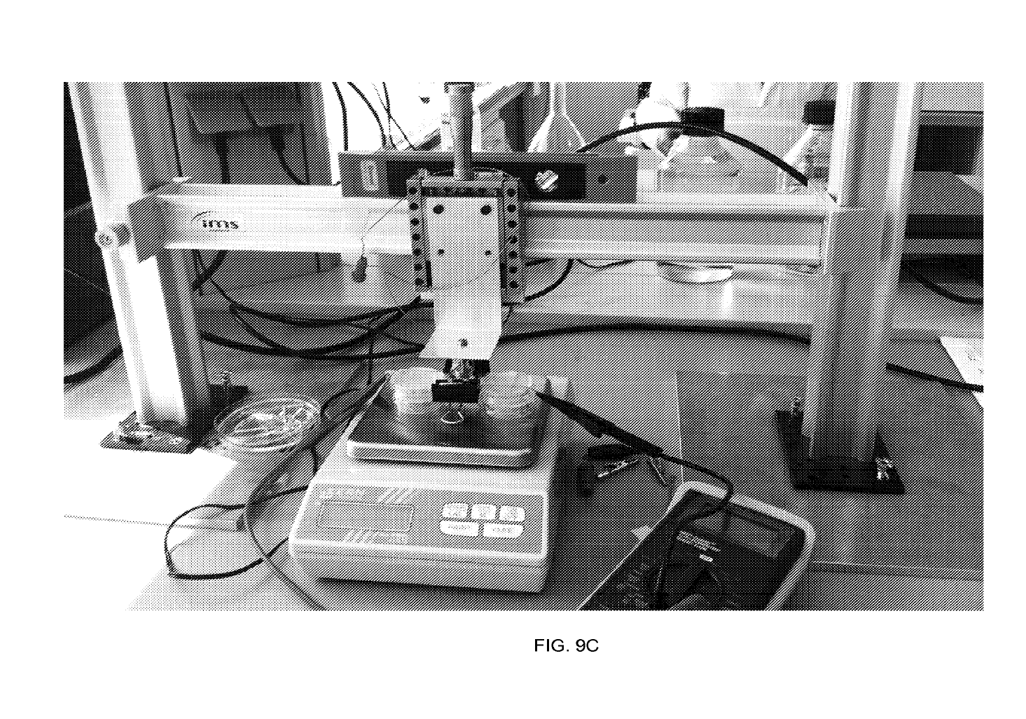

To measure R, ΔR, and P, the apparatus depicted schematically in FIGS. 9A and 9B was used. The foam material to be analyzed was placed on a glass slide. The electrical contacts were made with tin wires on which a pressure, referred to here as contact pressure, is applied by way of insulated clamps. The electrical circuit is completed by connection to a multimeter or an impedance analyzer. Supports underneath the glass slide were needed in order to apply a pressure on the wires without perturbing the measurements. This setup was placed on a weighing scale or balance. A photograph of the apparatus used is shown in FIG. 9C.

The mass applied on the sample foam material allows for the determination of the pressure P, referred to here as piezoelectric-related pressure, which is related to the mass applied according to the equation:

Pressure=mg/(surface area of application)

where m is the mass and g is the acceleration due to gravity.

The piezoelectric-related pressure was applied by a round, flat metal object of known mass that is electrically-isolated from the sample foam by parafilm. A bubble level was used to verify that the pressure applied to the sample foam was homogeneous. The surface area of application was determined by the diameter of the metal object (1 cm) and the width of the sample (1-2 mm depending on the particular foam). The width of the sample was about 5 times smaller than the diameter of the metal object. Thus, the surface area on which the pressure was applied was approximated as a rectangle of 1 cm length and 1-2 mm width.

The Young's modulus of a material, denoted E, corresponds to the theoretical value of the stress to be applied to a material to obtain a deformation of 100%. Young's moduli of the inventive foams were determined by plotting the stress as a function of deformation. The slope of the graph, or linear approximation thereof, gives an approximate value for Young's modulus. With Young's modulus of the foam known, the gauge factor K is determined by plotting “ΔR/R” as a function of “P/E”, wherein the slope of the resulting graph gives the gauge factor.

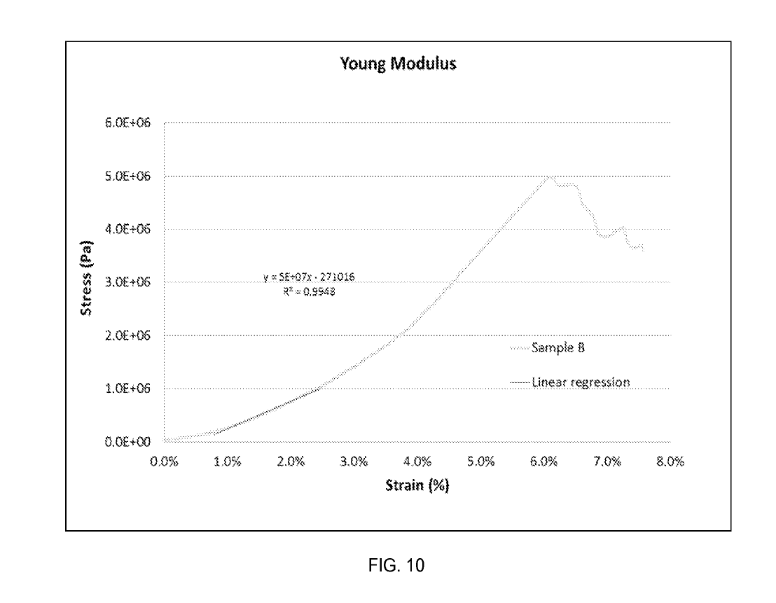

The plot of the stress for 2 of the inventive foams as a function of the percent strain is shown in FIG. 10.

In the portion of the graph of interest (i.e. stress in the range of 10⁵-10⁶ Pa), the curve is nearly linear. The slope of this portion of the graph gives a good approximation of Young's modulus for the inventive foams analyzed.

The Young's moduli of the inventive foams range from 0.05 to 0.1 Gpa, which is of the same order of magnitude as rubber, as compared in Table 4 below.

TABLE 4

| Material | Young's modulus (Gpa) |
|---|---|
| Rubber | 0.001-0.1 |
| Inventive foam material | 0.05-0.1 |
| Paper | 3-4 |
| Iron | 196 |
| Vulcanized rubber | 2.8 |

Once the Young's modulus of the material was known, the gauge factor was determined.

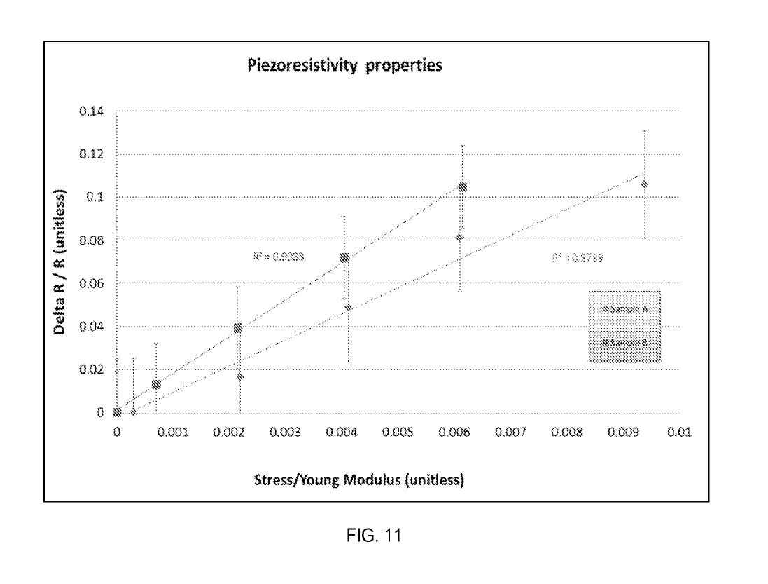

The gauge factor K was determined by plotting “ΔR/R” as a function of “P/E”, wherein the slope of the resulting graph gives the gauge factor. The plot is shown in FIG. 11.

The inventive foams studied were those characterized by a gelation time of 60 or 90 minutes and rinsed for 60 minutes without stirring. Their gauge factors were respectively 12.1 and 17.1. As shown in Table 5 below, these values are greater than those found for metals, which have gauge factors of about 2. However, in metals, the conductivity does not change and the change in resistance is only due to the geometry change of the induced stress. The application of stress changes the conductivity of the inventive foams, although the change is smaller than that of existing commercial piezoresistive materials, which are composed mostly of amorphous silicon and characterized by gauge factors of from 35 to 200.

TABLE 5

| Material | Gauge factor |
|---|---|
| Metal | ~2 |
| Inventive foam materials | 12.1-17.1 |
| Amorphous silicon (Kulite) | 35-200 |

An analysis of unwashed foams showed a decrease resistance in a non-linear manner when subjected to an applied pressure. Considering the finding that the unwashed foams generally have pores, the application of pressure may cause compression of the pores, enhancing contact between the PEDOT chains and, thus, enhancing conductivity.

### EXAMPLE 5

### Applications

These results described herein make practical the ability to manufacture pressure sensors, switches, and other electronic devices comprising the foams of the present invention as a piezoresistive element.

1. A polymer composition comprising:
(a) at least one electrically conductive polymer,
(b) optionally one or more polymeric acid dopants,
(c) at least one ionic liquid,
(d) a liquid medium, and
(e) optionally one or more additives.

2. (canceled)

3. The polymer composition according to claim 1, wherein the ratio of the total amount by weight of the ionic liquid to the total amount by weight of the electrically conductive polymer is from about 1:1 to about 45:1.

4. The polymer composition according to claim 1, wherein the at least one electrically conductive polymer comprises at least one polythiophene polymer comprising monomeric units according to structure (I.a), wherein Q is S.

5. (canceled)

6. The polymer composition according to claim 1, comprises one or more polymeric acid dopants, wherein the polymeric acid dopant is a water soluble polymeric acid dopant.

7.-10. (canceled)

11. The polymer composition according to claim 1, wherein the at least one ionic liquid comprises 1-ethyl-3-methylimidazolium tetracyanoborate.

12. A process for forming a polymer gel, the process comprising:
(I) forming the polymer composition according to claim 1 by a process comprising contacting, in a liquid medium:
an electrically conductive polymer,
(ii) optionally one or more polymeric acid dopants,
(iii) an ionic liquid,
(iv) optionally one or more additives, wherein the amount of ionic liquid is effective to gel the electrically conductive polymer, and
(II) allowing the gel to form.

13. (canceled)

14. (canceled)

15. The polymer gel made by the process according to claim 12.

16. A process for forming a polymer foam, the process comprising:
(I) forming a polymer composition according to claim 1 by a process comprising contacting, in a liquid medium:
(i) an electrically conductive polymer,
(ii) optionally one or more polymeric acid dopants,
(iii) an ionic liquid,
(iv) optionally one or more additives, wherein the amount of ionic liquid is effective to gel the electrically conductive polymer,
(II) allowing the gel to form, and
(III) removing from the gel any liquid remaining on or in the gel.

17. The process according to claim 16, further comprising rinsing the gel with a rinse liquid prior to the step of removing from the gel any liquid remaining on or in the gel.

18. The process according to claim 17, wherein rinsing the gel with a rinse liquid is performed with or without agitation.

19. The process according to claim 17, wherein the rinse time is from about 1 minute to about 24 hours.

20. The process according to claim 16, wherein the gelation time is from about 1 minute to about 150 minutes.

21. The process according to claim 16, wherein the step of removing from the gel any liquid remaining on or in the gel is performed by freeze-drying (lyophilization) or heating under an infrared lamp.

22. A polymer foam formed by the process according to claim 16.

23. The polymer foam according to claim 22, wherein the conductivity is from about 10 S/cm to about 120 S/cm.

24. The polymer foam according to claim 22, wherein the polymer foam is purely resistive over a frequency range of from about 1 Hz to about 10⁵ Hz.

25. The polymer foam according to claim 22, wherein the Young's modulus of the polymer foam is from about 0.01 GPa to about 0.2 GPa.

26. The polymer foam according to claim 22, wherein the gauge factor of the polymer foam is from about 5 to about 20.

27. A piezoresistive device comprising:
(I) a polymer foam according to claim 22; and
(II) a first and second electrode.

28. An electronic device, comprising:
(a) an anode layer,
(b) a cathode layer,
(c) an electroactive layer disposed between the anode layer and the cathode layer,
(d) optionally, a buffer layer,
(e) optionally, a hole transport layer, and
(f) optionally, an electron injection layer, wherein at least one of the anode layer, the cathode layer, and, if present, the buffer layer comprises a polymer foam according to claim 22.

29. -35. (canceled)
